(19) United States
(12) Patent Application Publication
(10) Pub. No.: US 2026/0114100 A1
(43) Pub. Date: Apr. 23, 2026

(54) COLOR CONVERSION FILM ARRAY AND PRODUCING METHOD THEREOF

(71) Applicant: National Taiwan University, Taipei (TW)

(72) Inventors: Ching-Fuh Lin, Taipei (TW); Yen-Chia Cheng, Taipei (TW)

(21) Appl. No.: 18/983,116

(22) Filed: Dec. 16, 2024

(30) Foreign Application Priority Data
Oct. 23, 2024 (TW) 113140267

(51) Int. Cl. H10H 29/851; H01L 25/075; H10H 29/80

(52) U.S. Cl. CPC H10H 29/8514; H10H 29/8512; H10H 29/942; H10W 90/00

(57) ABSTRACT

A color conversion film array includes a first color conversion sub-film array and a second color conversion sub-film array, wherein each color conversion sub-film includes a photoresist and an organic fluorescent material, and may further includes inorganic oxide nanoparticles. The organic fluorescent materials are all hydrocarbons that are friendly to the environment. The manufacture of the first and second color conversion sub-film arrays merely requires exposure and development, and the process temperature is lower than 120° C., which can avoid degradation of the organic fluorescent material. The pixel density of the manufactured color conversion film array exceeds 5000 PPI.

### CROSS-REFERENCE TO RELATED APPLICATIONS

The entire contents of Taiwan Patent Application No. 113140267, filed on Oct. 23, 2024, from which this application claims priority, are expressly incorporated herein by reference.

### BACKGROUND OF THE INVENTION

### 1. Field of the Invention

The present invention relates to a color conversion array applied to a micro-LED display and fabricating method thereof.

### 2. Description of Related Art

Micro Light-Emitting Diode (Micro-LED) is regarded as the next generation display with extremely small size and ultra-high resolution. Due to technical problems with mass transfer, micro-light-emitting diode displays are still unable to be mass-produced. Mass transfer refers to transferring the integrated red, green, and blue micro-light-emitting diode dies to a display substrate. Because the size of a micro-light-emitting diode die is only a few microns, it is difficult to transfer the dies in a large quantity and large area manner.

Several promising techniques, such as elastomer stamp transfer, electrostatic transfer, (electro) magnetic transfer, laser-induced transfer, transfer printing, and fluidic self-assembly (FSA) are typical types of the mass transfer techniques for Micro-LED displays (Huang, Y., Hsiang, E. L., Deng, M. Y., & Wu, S. T. (2020). Mini-LED, Micro-LED and OLED displays: present status and future perspectives. Light: Science & Applications, 9(1), 105.).

In order to solve the problem of mass transfer, Dawson et al. proposed a color conversion technology to manufacture color-converted full-color micro-light-emitting diode array suitable for mass production. The color conversion technology employs a mono-colored micro-light-emitting diode array to emit an excitation light and a full-color conversion layer excited by the excitation light to achieve a full-color micro-light-emitting diode display. Generally the display consists of a bottom UV micro-LED array and a layer of three color (blue, green, and red)-conversion materials or consists of a bottom blue micro-LED array and a layer of two color (green and red)-conversion materials.

Quantum confinement effects give rise to unique optical and electronic properties in Nanocrystal Quantum Dots (NQDs). The emission wavelength can be adjusted by adjusting the size of the quantum dots, allowing a narrower emission spectrum with a greater intensity. Color conversion by using quantum dots is a key method to achieve full-color micro-light-emitting diode displays, but there are still many problems to be solved. The major limitations of QDs in practical applications are their thermal and oxidative instabilities. The degradation of QDs reduces the reliability and life of the display. In addition, the conversion efficiency of QDs is low, with only about 30%, greatly reducing the performance of the display. Furthermore, with a smaller size and a larger surface area, QDs nanoparticles are easily affected by the environment. A core-shell structure is therefore designed to protect the quantum dots, leading to a larger particle size. Because only the “core” is responsible to absorb the excitation light and emit a light, the number of photons emitted per unit volume is decreased.

Therefore, a large amount of quantum dot materials are required to increase the light intensity, resulting in a thicker pixel structure and a larger pixel aspect ratio, which is not conducive to the production of micro-light-emitting diode pixels and pixel miniaturization. In addition, color conversion QDs contain cadmium, which is harmful to human and easily pollutes the environment.

### SUMMARY OF THE INVENTION

In one aspect, a color conversion film array is provided with a microstructure array, a first color conversion sub-film array, a second color conversion sub-film array, and a shielding layer. The microstructure array comprises a plurality of microstructures, and a plurality of first grooves, a plurality of second grooves, and a plurality of third grooves are formed between neighboring microstructures of the plurality of microstructures. The first color conversion sub-film array comprises a plurality of first color conversion sub-films, wherein each first color conversion sub-film is disposed in one corresponding first groove and comprises a first organic fluorescent material and a first photoresist. The second color conversion sub-film array comprises a plurality of second color conversion sub-films, wherein each second color conversion sub-film is disposed in one corresponding second groove and comprises a second organic fluorescent material and a second photoresist. The shielding layer covers side wall and an upper surface of each of the plurality of microstructures. The first side of the color conversion film array is aligned with a micro-LED array to form a micro-LED display.

In some embodiments, each first color conversion sub-film and/or each second color conversion sub-film further comprises inorganic oxide nanoparticles. In some embodiments, each of the plurality first color conversion sub-films and the plurality of second color conversion sub-films comprises an incident surface adjacent to the micro-LED array and a light-emitting surface, and an area of the incident surface is larger than an area of the light-emitting surface. In some embodiments, the color conversion film array further comprises a color-purifying film on a second side of the color conversion film array. In some embodiments, the color conversion film array further comprises a protective layer between the shielding layer and each of the plurality of first color conversion sub-films and between the shielding layer and each of the plurality of the second color conversion sub-films. In some embodiments, wherein the microstructure array is a trapezoidal structure array comprising a plurality of trapezoidal structures, each of the plurality of trapezoidal structures comprises an upper base and a lower base, and a length of the upper base is less than a length of the lower base. In some embodiments, a resolution of the color conversion film array is greater than 5000 PPI.

In another aspect, a method for fabricating a color conversion film array is provided with the steps of: depositing a first color conversion solution on a substrate and solidifying it into a first color conversion film, wherein the first color conversion solution comprises a first organic fluorescent material and a first photoresist; patterning the first color conversion film to form a first color conversion sub-film array; depositing a first protective layer to cover the first color conversion sub-film array; depositing a second color conversion solution and solidifying it into a second color conversion film, wherein the second color conversion solution comprises a second organic fluorescent material and a second photoresist; patterning the second color conversion film to form a second color conversion sub-film array; depositing a second protective layer to cover the second color conversion sub-film array; depositing a shielding layer to cover the first color conversion sub-film array and the second color conversion sub-film array; depositing a photoresist layer to cover the shielding layer; patterning the photoresist layer to form a microstructure array between the first color conversion sub-film array and the second color conversion sub-film array and to expose top portions of the first color conversion sub-film array and top portions of the second color conversion sub-film arrays; etching the top portions of the first color conversion sub-film array and the top portions of the second color conversion sub-film arrays to form a color conversion film array.

In some embodiments, the method further comprises the following steps before the step of depositing the shielding layer: depositing a transparent solution and solidify it into a transparent film; patterning the transparent film to form a transparent sub-film array; and depositing a third protective layer to cover the transparent sub-film array.

In some embodiments, the first color conversion solution and/or the second color conversion solution further comprises inorganic oxide nanoparticles. In some embodiments, the method further comprises: combining a color-purifying film on a second side of the color conversion film array; removing the substrate; and aligning a first side of the color conversion film with a micro-LED array. In some embodiments, wherein the first color conversion sub-film array comprises a plurality of bell-shaped first color conversion sub-films and the first color conversion sub-film array comprises a plurality of bell-shaped second color conversion sub-films.

In another aspect, a method for fabricating a color conversion film array is provided with the steps of: depositing a bottom layer on a substrate; depositing a first photoresist layer on the bottom layer and patterning the first photoresist layer to form a patterned first photoresist layer; employing the patterned first photoresist layer as a mask to etch the bottom layer to form a microstructure array comprising a plurality of microstructures, wherein a plurality of first grooves, a plurality of second grooves, and a plurality of third grooves are formed between neighboring microstructures; depositing a second photoresist layer and patterning it to form a patterned second photoresist layer that fills the plurality of first grooves, the plurality of second grooves, and the plurality of third grooves; depositing a shielding layer to cover the microstructure array and the patterned second photoresist layer; removing the patterned second photoresist layer to expose the plurality of first grooves, the plurality of second grooves, and the plurality of third grooves; depositing a first color conversion solution and solidifying it into a first color conversion film, patterning the first color conversion film to form a first color conversion sub-film array filling the plurality first grooves, wherein the first color conversion solution comprises a first organic fluorescent material and a first photoresist; depositing a protective layer to cover the first color conversion sub-film array and the microstructure array; and depositing a second color conversion solution and solidifying it into a second color conversion film, patterning the second color conversion film to form a second color conversion sub-film array filling the plurality of second grooves, wherein the second color conversion solution comprises a second organic fluorescent material and a second photoresist.

In some embodiments, wherein the first color conversion solution and/or the second color conversion solution further comprises inorganic oxide nanoparticles. In some embodiments, the method further comprises combining a color-purifying film on top of the color conversion film array.

In another aspect, a method for fabricating a color conversion film array is provided with the steps of: depositing a first photoresist layer on a substrate; patterning the first photoresist layer to form a microstructure array comprising a plurality of microstructures, wherein a plurality of first grooves, a plurality of second grooves, and a plurality of third grooves are formed between neighboring microstructures; depositing a first protective layer to cover the microstructure array; depositing a second photoresist layer and patterning it to form a patterned second photoresist layer that fills the plurality of first grooves, the plurality of second grooves, and the plurality of third grooves; depositing a shielding layer to cover the microstructure array and the patterned second photoresist layer; removing the patterned second photoresist layer to expose the plurality of first grooves, the plurality of second grooves, and the plurality of third grooves; depositing a first color conversion solution and solidifying it into a first color conversion film, patterning the first color conversion film to form a first color conversion sub-film array filling the plurality of first grooves, wherein the first color conversion solution comprises a first organic fluorescent material and a first photoresist; depositing a second protective layer to cover the first color conversion sub-film array and the microstructure array; and depositing a second color conversion solution and solidifying it into a second color conversion film, patterning the second color conversion film to form a second color conversion sub-film array filling the plurality of second grooves, wherein the second color conversion solution comprises a second organic fluorescent material and a second photoresist.

In some embodiments, the first color conversion solution and/or the second color conversion solution further comprises inorganic oxide nanoparticles. In some embodiments, the method further comprises: combining a color-purifying film on top of the color conversion film array. In some embodiments, the method further comprises: depositing a transparent solution and solidifying it into a transparent film, patterning the transparent film to form a patterned transparent sub-film array that fills the plurality of third grooves.

In another aspect, a color conversion film array is provided with a first color conversion sub-film array and a second color conversion sub-film array. The first color conversion sub-film array comprises a plurality of first color conversion sub-films. Each of the first color conversion sub-films comprises a first organic fluorescent material, a first polymer, and a first inorganic oxide nanoparticle. The second color conversion sub-film array comprises a plurality of second color conversion sub-films. Each of the second color conversion sub-films comprises a second organic fluorescent material, a second polymer, and a second inorganic oxide nanoparticle. A first side of the color conversion film array is aligned with a micro-LED diode array to form a micro-LED display.

In some embodiments, both the first polymer and the second polymer comprise polyvinyl butyral (PVB). In some embodiments, each of the plurality first color conversion sub-films and each of the plurality of second color conversion sub-films comprises an upper layer and a lower layer, and the upper layer differs from the lower layer in that the lower layer does not include the inorganic oxide nanoparticle.

The present disclosure employs photolithography to produce a full-color conversion film array aligned with a micro-LED array. Mass transfer is unnecessary and the resolution the full-color conversion film array exceeds 5000 PPI. The organic fluorescent materials are all hydrocarbons that are friendly to the environment. The first and second color conversion sub-film arrays are made in a low cost and simple manner, with the process temperature lower than 120° C., which can avoid degradation of the organic fluorescent material. The shielding layer is used to avoid color crosstalk between neighboring pixels, and to reflect the light hitting the side walls of the color conversion sub-film, thereby increasing the emission intensity.

### BRIEF DESCRIPTION OF THE DRAWINGS

FIG. 1 is a schematic diagram showing a method for manufacturing a color conversion film array in accordance with an embodiment of the present invention.

FIG. 2 shows photoluminescence (PL) spectra of four second color conversion films made by this invention.

FIG. 3A is a microscope photo showing a produced second color conversion sub-film array combined with a blue LED with an emission central wavelength of 460 nm.

FIG. 3B is a microscope photo showing the prepared first and second color conversion sub-film arrays combined with a blue LED with emission wavelength of 460 nm.

FIGS. 4A-4D are schematic diagrams showing a method for manufacturing a color conversion film array according to another embodiment of the present invention.

FIG. 5A shows photoluminescence (PL) spectra of five color conversion films (with different amount of TiO₂ NPs) produced by this invention.

FIG. 5B shows photoluminescence (PL) spectra of the respective superimposed color conversion films of FIG. 5A.

FIG. 5C shows photoluminescence (PL) spectra of another five color conversion films (with different amount of TiO₂ NPs) produced by this invention.

FIG. 5D shows photoluminescence (PL) spectra of the respective superimposed color conversion films of FIG. 5C

FIG. 6A shows photoluminescence (PL) spectra of another five color conversion films (with different composition of SiO₂ NPs) produced by this invention.

FIG. 6B shows photoluminescence (PL) spectra of the respective superimposed color conversion films of FIG. 6A.

FIG. 7A shows photoluminescence (PL) spectra of another five color conversion films (with different composition of ZnO NPs) produced by this invention.

FIG. 7B shows photoluminescence (PL) spectra of the respective superimposed color conversion films of FIG. 7A.

FIG. 8A shows photoluminescence (PL) spectra of another five color conversion films (with different composition of ZnO NPs) produced by this invention.

FIG. 8B shows photoluminescence (PL) spectra of the respective superimposed color conversion films of FIG. 8A.

FIG. 9 show line charts of nanoparticle composition (wt %) versus quantum yield (%) of the produced color conversion films with different nanoparticles.

FIG. 10 show line charts of nanoparticle composition (wt %) versus emission peak of the produced color conversion films with different nanoparticles.

FIG. 11 is a schematic diagram showing a method for fabricating a color conversion film array in accordance with another embodiment of the present invention.

FIG. 12 is a schematic diagram showing a method for fabricating a color conversion film array in accordance with another embodiment of the present invention.

FIG. 13 is a photo of a trapezoidal microstructure array produced by reactive ion etching according to the method described in FIG. 11

FIG. 14 is a photo of a trapezoidal microstructure array produced according to the method described in FIG. 12.

FIG. 15 shows PL spectra of three produced second color conversion films.

FIG. 16 shows CIE 1931 chromaticity diagram of combining a first color conversion film, a second color conversion film, and a transparent film produced by the present invention.

FIG. 17 shows CIE 1931 chromaticity diagram of combining a first color conversion film, a second color conversion film, a transparent film, and a color-purifying film of the present invention.

### DETAILED DESCRIPTION OF THE PREFERRED EMBODIMENT

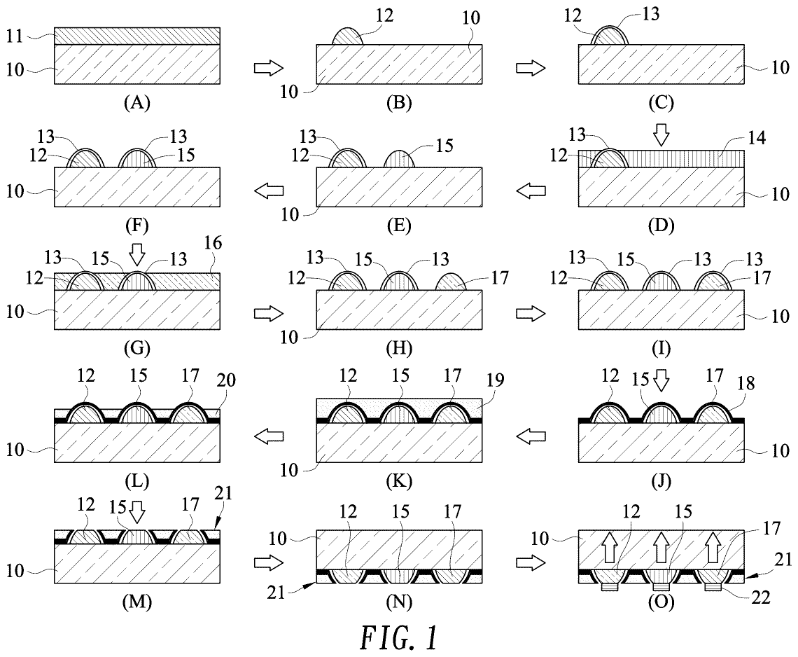

FIG. 1 is a schematic diagram showing a method for manufacturing a color conversion film array in accordance with an embodiment of the present invention. As shown in step (A), a first color conversion solution is deposited on a substrate 10 and then solidified into a first color conversion film 11. The substrate 10 can be made of any material, preferably a transparent material, such as glass. As shown in step (B), the first color conversion film 11 is patterned, by e.g., exposure and development, to form a first color conversion sub-film array 12. As shown in step (C), a protective layer 13, such as silicon dioxide, may be deposited over the first color conversion sub-film array 12. As shown in step (D), a second color conversion solution is deposited on the surface of the substrate 10 and then solidified into a second color conversion film 14. As shown in step (E), exposure and development may be used to pattern the second color conversion film 14 to form a second color conversion sub-film array 15. As shown in step (F), another protective layer 13, such as silicon dioxide, may be deposited over the second color conversion sub-film array 15. As shown in step (G), a transparent solution may be deposited on the surface of the substrate 10 and then solidified into a transparent film 16. As shown in step (H), the transparent film 16 is patterned using exposure and development to form a transparent sub-film array 17. As shown in step (I), another protective layer 13, such as silicon dioxide, may be deposited over the transparent sub-film array 17. As shown in step (J), a shielding layer 18 is deposited to cover the first color conversion sub-film array 12, the second color conversion sub-film array 15, and the transparent sub-film array 17. The shielding layer 18 is typically made of a metal with high reflectivity, such as chromium or silver. In some embodiments, the shielding layer 18 may be made of a black photoresist. As shown in step (K), a photoresist layer 19 is deposited to cover the shielding layer 18. As shown in step (L), the photoresist layer 19 is patterned using exposure and development to form a patterned photoresist layer 20 (also referred as a microstructure array) and to expose top portions of the first color conversion sub-film array 12, the second color conversion sub-film array 15, and the transparent sub-film array 17. As shown in step (M), the top portions of the first color conversion sub-film array 12, the second color conversion sub-film array 15, and the transparent sub-film array 17 are removed by etching, thereby forming a color conversion film array 21. As shown in step (N), the color conversion film array 21 is inverted. As shown in step (O), the color conversion film array 21 is aligned with a micro-LED array 22 to form a micro-LED display. In the preferred embodiment, the micro-LED array 22 emits blue light. In another embodiment, the micro-LED array 22 emits ultraviolet light.

As shown in steps (A) and (D) of FIG. 1, the first color conversion solution and the second color conversion solution may be deposited by a manner that includes but is not limited to: spin coating, spray coating, or ink-jet printing. In some embodiments, a spin coater and a hotplate are used to deposit the color conversion solution and solidify it into a film. First, the substrate is held on a spindle head of the spin coater by a vacuum chunk and a coating solution is loaded on the surface of the substrate, and then the spindle head drives the substrate to rotate and to generate centrifugal force, so that the coating solution is evenly spin-coated on the surface of the substrate. The speed of the spin coater can be controlled. The higher the rotation speed, the thinner the film can be obtained, and vice versa. The substrate is then placed on the hot plate to evaporate the solvent, so as to form a uniform thin film on the substrate. In the embodiment of FIG. 1, the steps of depositing the first or second color conversion solution and then forming the first or second color conversion film, depositing the transparent solution and then forming the transparent film, depositing the photoresist layer, and depositing the protective layer can be performed using the method described above. In the embodiment of FIG. 1, the order of forming the first color conversion film and the second color conversion film can be reversed. In some embodiments, the order of forming the first color conversion film, the second color conversion film, and the transparent film may be changed.

Preferably, the compositions of the first color conversion solution and the second color conversion solution each include an organic fluorescent material and a photoresist. In some embodiments, each of the first color conversion solution and the second color conversion solution further includes nanoparticles (NPs) with size ranging from 1 nm to 100 nm. The nanoparticles may be spherical or rod-shaped, or have form of other shapes. In some embodiments, the first and/or second color conversion solution contains nanoparticles with varied shapes. The nanoparticles is used to lengthen the optical path length (also referred to as the ‘optical path’ for brevity) of the light (such as blue light) in the color conversion sub-film, which is emitted by the micro-light emitting diode array, thereby increasing the light absorption of the color conversion sub-film. In some embodiments, the nanoparticles are inorganic nanoparticles, including, e.g., TiO₂, SiO₂, and/or ZnO nanoparticles. In some embodiments, the nanoparticles comprise silver nanoparticles (which may contain silver oxide). In some examples, the nanoparticles are made of TiO₂ with particle size of 15 nm, 170 nm, or 240 nm.

An example of preparing the first color conversion solution is described as follows: (1) putting 10 mg of Coumarin6 phosphor into a sample jar; (2) adding 5 mL of negative photoresist (Everlight Chemical EOC170) and put a magnetic stirrer in the sample jar; (3) stirring the prepared color conversion solution at 450 rpm for 24 hours (overnight); (4) losing a lid of the sample jar and put it into a vacuum pan for 20 minutes; (5) taking out the sample jar after confirming that there are no bubbles in the solution in the sample jar.

An example of preparing the second color conversion solution is the same as the preparation of the first color conversion solution, and the difference is that the Coumarin6 phosphor in the first color conversion solution is replaced by DCJTB phosphor.

The following describes an example of fabricating a first color conversion film: (1) spin-coating hexamethyldisilazane (HMDS) on a glass substrate by using a spin coater (R405) with an initial speed 1000 rpm for 10 s and then a terminal speed 4000 rpm for 20 s; (2) baking the glass substrate by the hot plate with temperature 115° C. for 3 minutes to form a modified layer on the surface of the glass substrate (the modified layer is unnecessary in some embodiments); (3) spin-coating a first color conversion solution on the modified layer using the spin coater (R405) with an a speed of 650 rpm for 7 s. (4) placing the substrate on a dust-free paper for 15 minutes; (5) baking the substrate by the hot plate with temperature 110° C. for 5 minutes to form a first color conversion film.

The following describes an example of fabricating a first color conversion sub-film array: (1) employing an R431 mask aligner (MJB3) to expose the prepared first color conversion film for 55 s; (2) employing a developer (MF-319) to develop the prepared first color conversion film for 80 s; (3) cleaning and blow-drying the sample with DI water and then a nitrogen gun.

The following describes an example of fabricating a second color conversion film: (1) spin-coating hexamethyldisilazane (HMDS) on a glass substrate by using the spin coater (R405) with an initial speed 1000 rpm for 10 s and then a terminal speed 4000 rpm for 20 s; (2) baking the glass substrate by the hot plate with temperature 115° C. for 3 minutes to form a modified layer on the surface of the glass substrate (the modified layer is unnecessary in some embodiments); (3) spin-coating a second color conversion solution on the modified layer using the spin coater (R405) with an a speed of 650 rpm for 7 s; (4) placing the substrate on a dust-free paper for 15 minutes; (5) baking the substrate by the hot plate with temperature 110° C. for 5 minutes to form a second color conversion film.

The following describes an example of fabricating a second color conversion sub-film array: (1) employing an R431 mask aligner (MJB3) to expose the prepared second color conversion film for 55 s; (2) employing a developer (MF-319) to develop the prepared second color conversion film for 80 s; (3) cleaning and blow-drying the sample with DI water and then a nitrogen gun.

In the embodiments described above, the organic fluorescent materials used in the first color conversion film and the second color conversion film are not limited to Coumarin6 and DCJTB. The first and second color conversion sub-film arrays re-emit green light and red light after absorbing blue light. In other embodiments, other organic fluorescent materials can be employed to adapt the emission spectrum of the micro-light emitting diode array and/or to adapt the required re-emission wavelength. The photoresist and/or inorganic oxide nanoparticles used with the organic fluorescent material in the color conversion solution may also be adjusted as needed. In the embodiments described above, the first and second color conversion solutions use the same photoresist. In other embodiments, different photoresists may be used for the first and second color conversion solutions. In some embodiments, the transparent solution is replaced by a third color conversion solution, thereby forming a third color conversion film, which is then patterned into a third color conversion sub-film array.

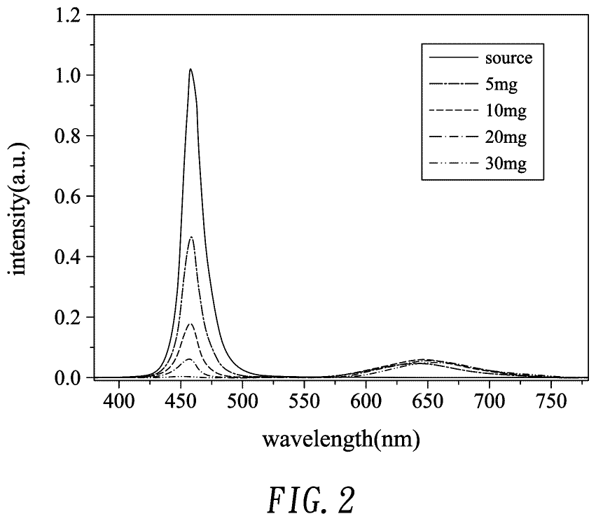

The following examples demonstrate to prepare four second color conversion solutions comprising DCJTB phosphors of 5 mg, 10 mg, 20 mg, and 30 mg respectively. Four second (red) color conversion films are formed and then put into an integrating sphere measurement system for measurement. The system employs a blue LED to emit an excitation light with a wavelength of 460 nm. FIG. 2 shows the photoluminescence (PL) spectra of the above four second color conversion films. Table 1 lists the quantum yield, blue light absorbance, emission peak wavelength, etc. of the four second color conversion films.

TABLE 1

| DCJTB | | blue light | emission peak |
|---|---|---|---|
| weight | quantum | absorbance | wave- |
| (mg) | yield (%) | (%) | length (nm) |
| 5 | 44.9 | 57.1 | 641 |
| 10 | 39.4 | 83.8 | 646 |
| 20 | 33.6 | 94.3 | 651 |
| 30 | 28.1 | 99.6 | 656 |

As shown in Table 1, as the amount of DCJTB increases, the blue light absorption increases while the quantum yield gradually decreases.

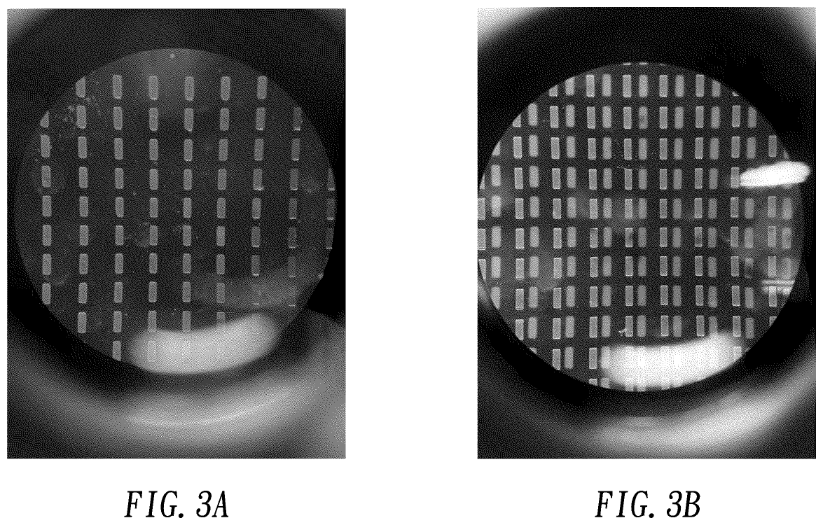

In one embodiment, through the above examples of fabricating the first and second color conversion sub-film arrays, both a first and a second color conversion sub-film arrays with pixel size of 20 μm×60 μm can be produced. FIG. 3A is a microscope photo showing the produced second color conversion sub-film array combined with a blue LED with an emission central wavelength of 460 nm. FIG. 3B is a microscope photo showing the prepared first and second color conversion sub-film arrays combined with the blue LED with emission wavelength of 460 nm.

In one embodiment, a first color conversion film is fabricated using the above-described method of fabricating a first color conversion film, and then the fabricated first color conversion film is patterned by exposure for 18 seconds and development for 45 seconds, so as to produce a first color conversion sub-film array with pixel size of 4 μm×4 μm. A second color conversion film is then fabricated using the above-described method of fabricating a second color conversion film, and then the fabricated second color conversion film is patterned by exposure of 35 seconds and development of 45 seconds, so as to produce a second color conversion sub-film array with pixel size of 4 μm×4 μm. The resolution of the produced color conversion film arrays exceed 5000 PPI (Pixels Per Inch), while most common LCD or OLED displays are less than 600 PPI.

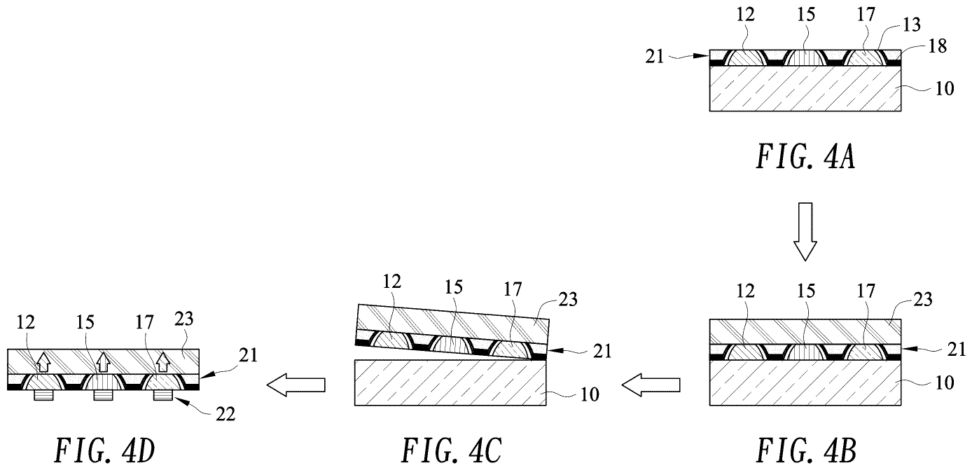

FIGS. 4A-4D are schematic diagrams showing a method for manufacturing a color conversion film array according to another embodiment of the present invention. The structure shown in FIG. 4A is equivalent to the structure shown in step (M) of FIG. 1 and may be fabricated using the method shown in steps (A)-(M) of FIG. 1. As shown in FIG. 4B, the color conversion film array 21 is combined with a color-purifying film (CPF) 23 provided by the team of Professor Zhi Ting Ye of National Chung Cheng University. The color-purifying film 23 allows one or more specific wavebands of light to transmit. In some embodiments, the color-purifying film 23 merely allows red light and green light wavelength bands to pass through. In the exemplary embodiment, the transmittable wavelength bands of the color-purifying film 23 include red light 627˜642 nm and green light 514˜528 nm. The full width at half maximum (FWHM) of emission spectrum of the color conversion film array 21 combined with the color-purifying film 23 can be greatly reduced to 18˜22 nm, thereby improving the color purity of light emission. In addition, the color-purifying film further reflects the wavelength band that is non-transmitted (such as blue light) back to the color conversion film array 21 so that it is converted again, thereby improving the conversion efficiency. As shown in FIG. 4C, the substrate 10 is lifted-off. As shown in FIG. 4D, the color conversion film array 21 is aligned with a micro-LED array 22 to form a micro-LED display.

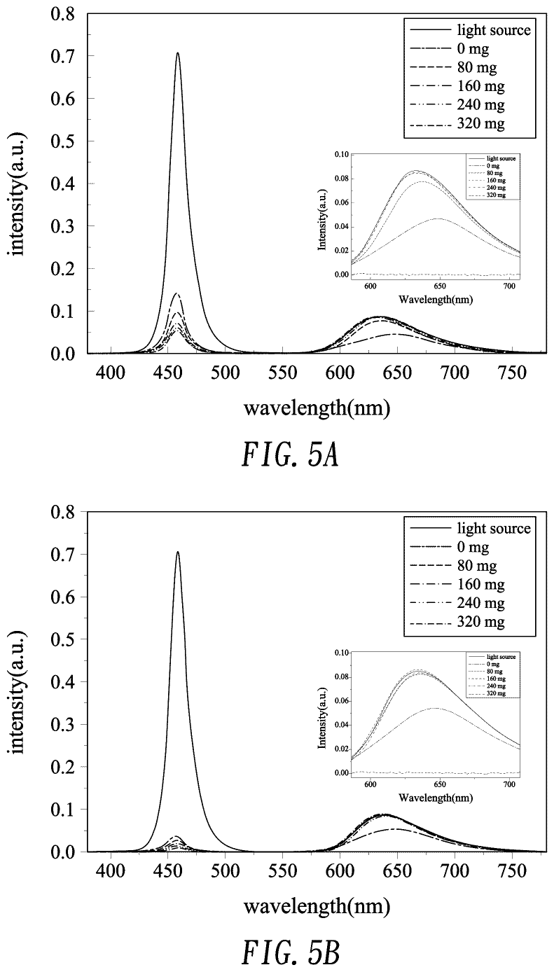

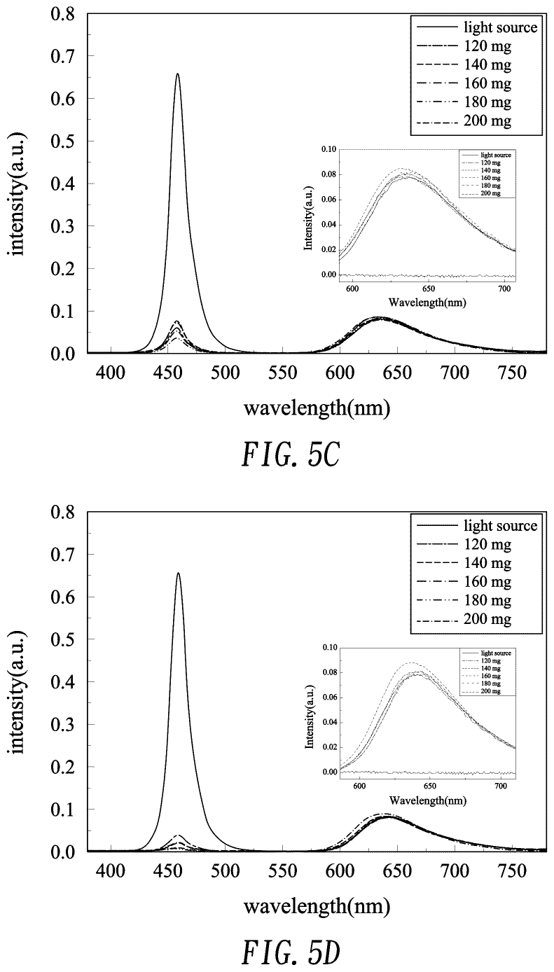

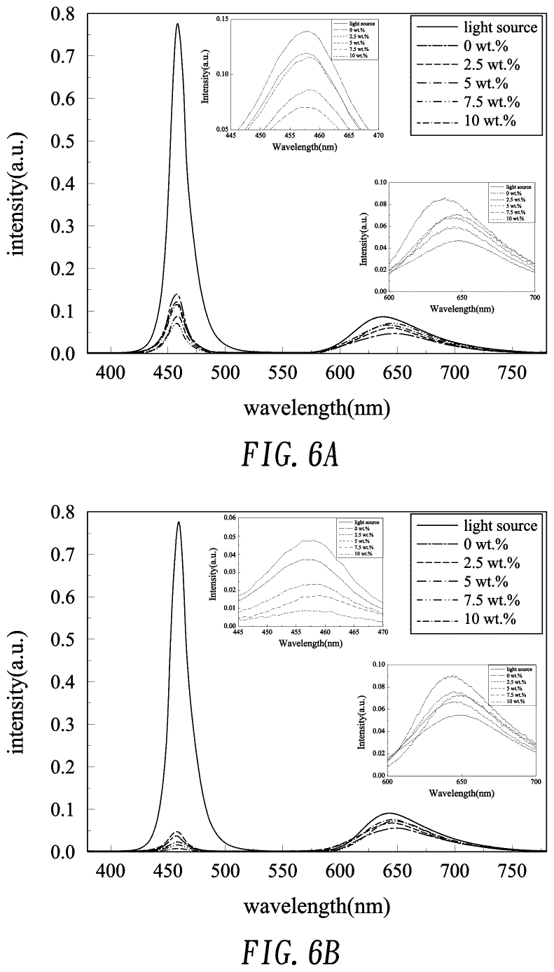

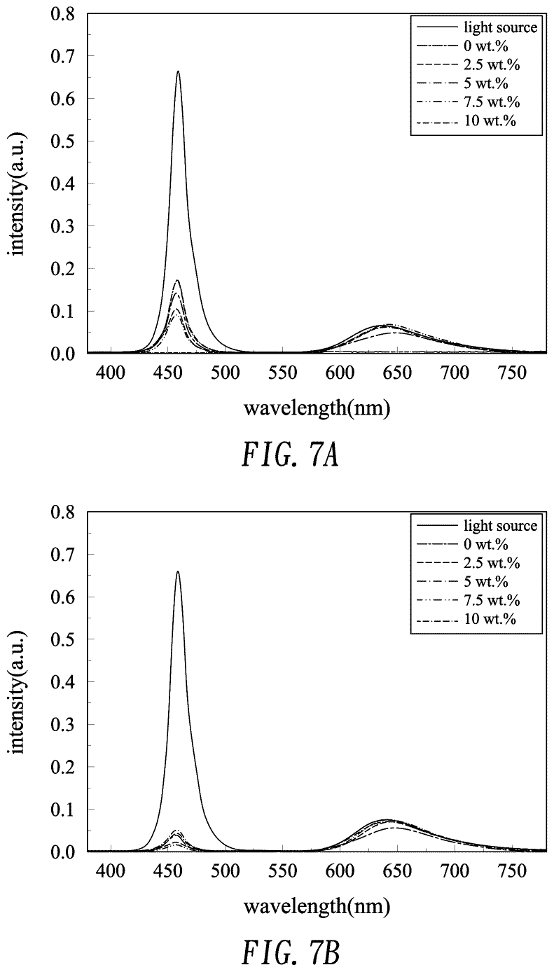

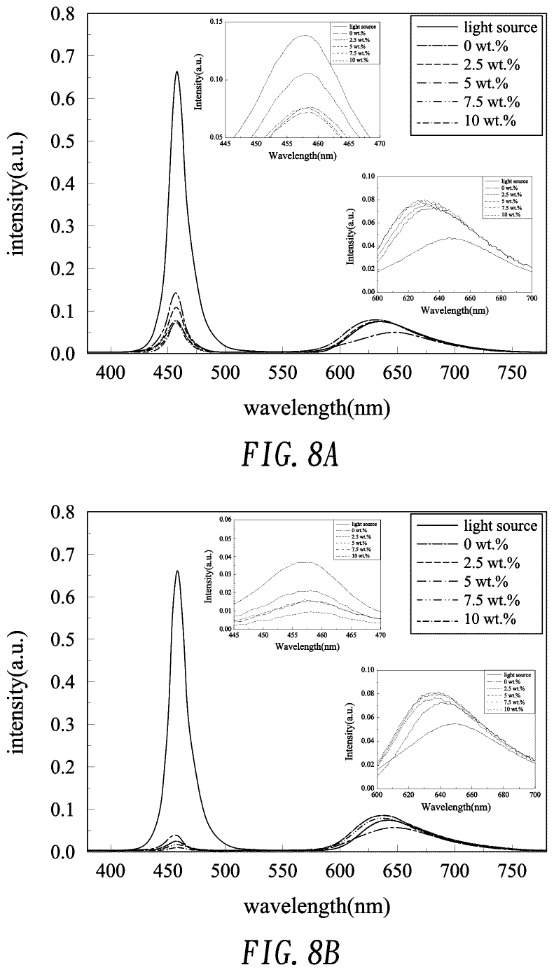

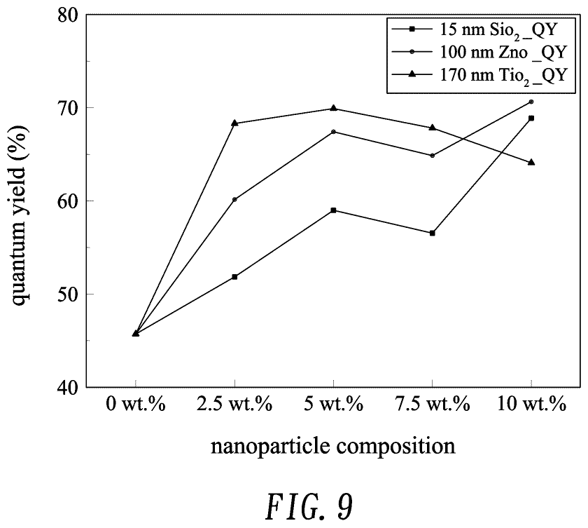

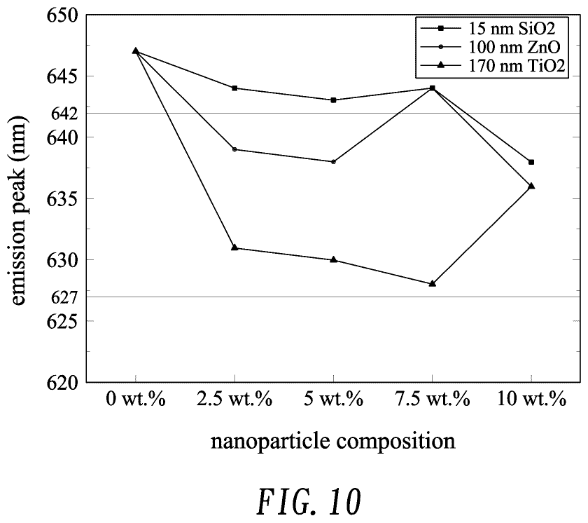

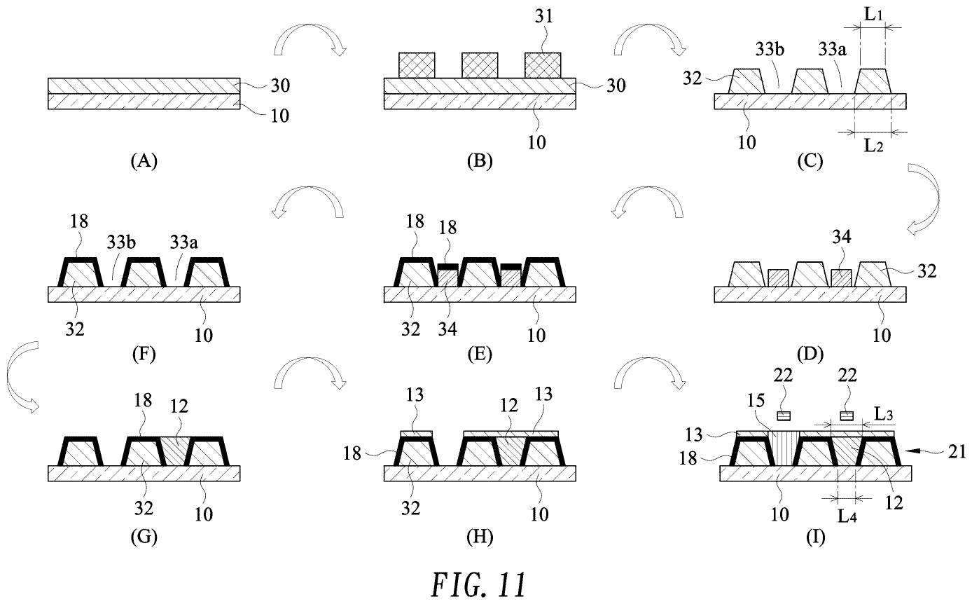

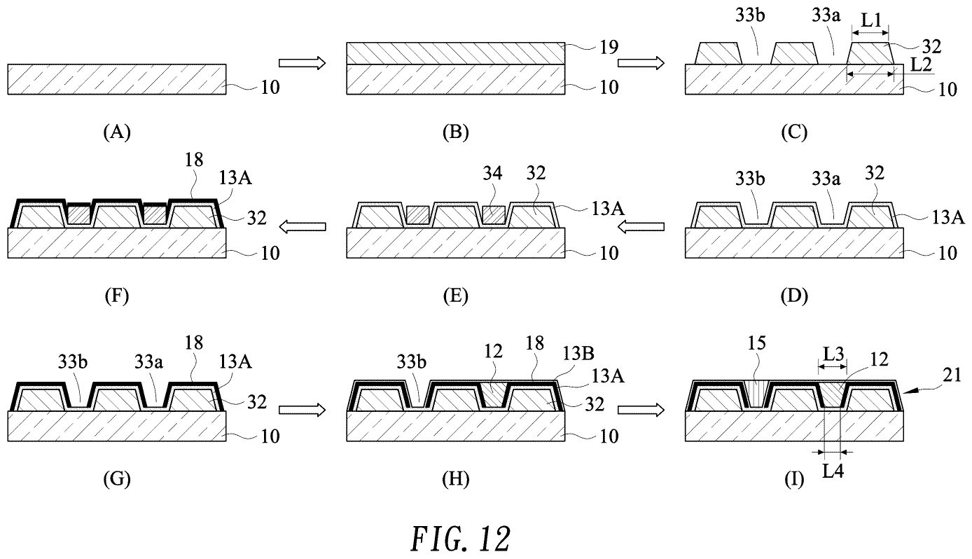

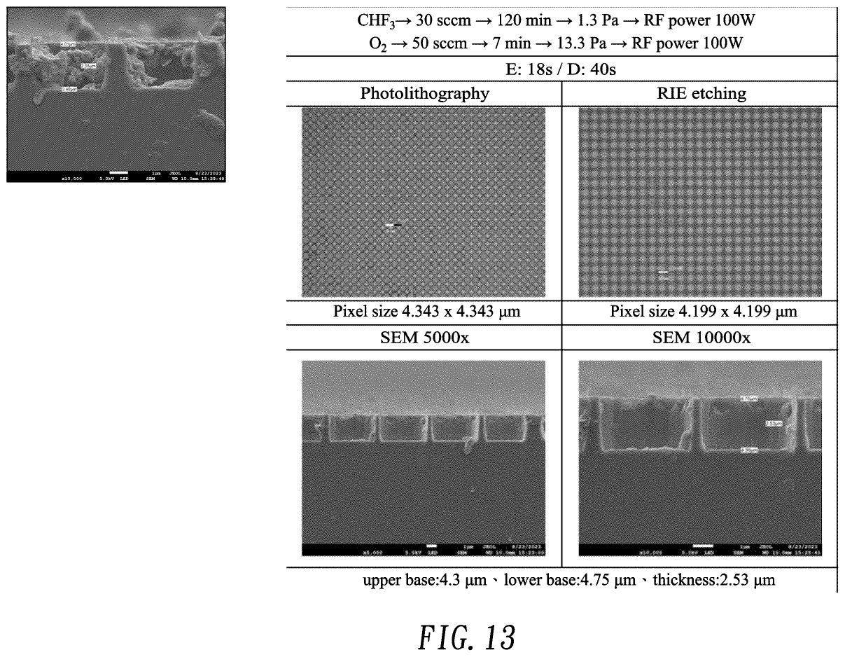

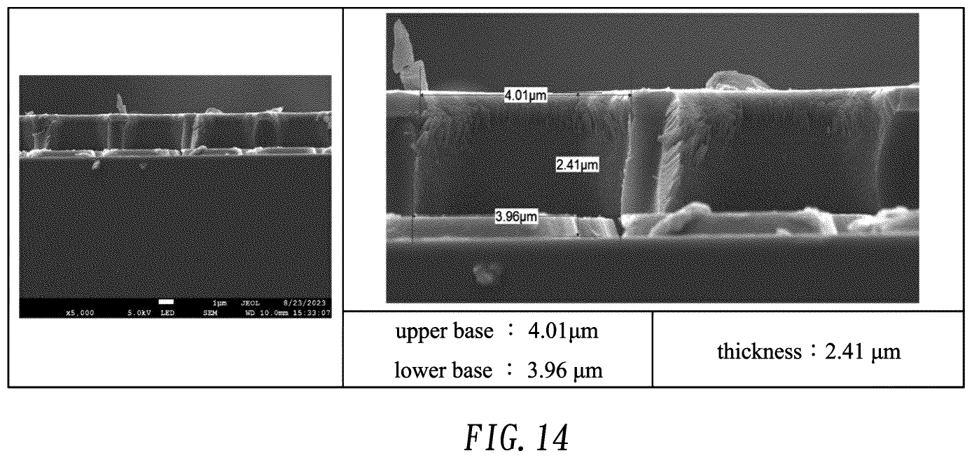

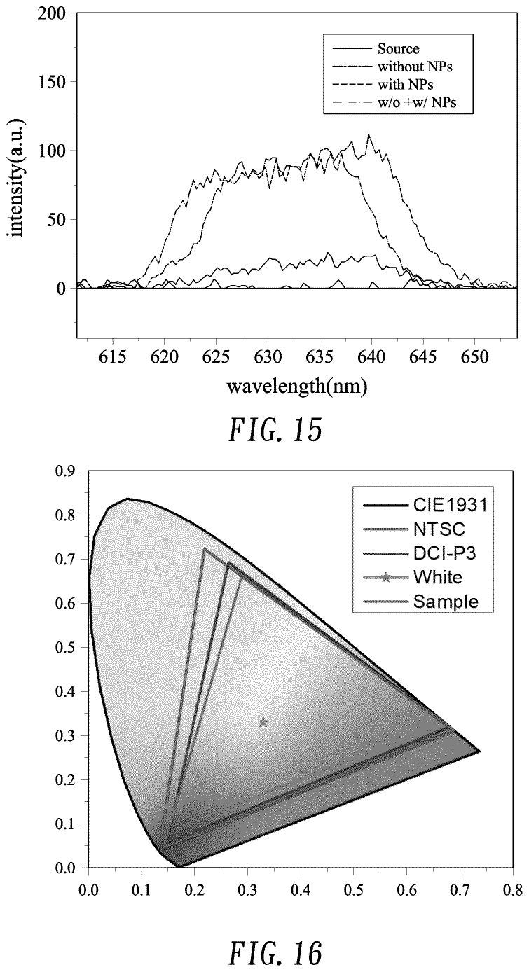

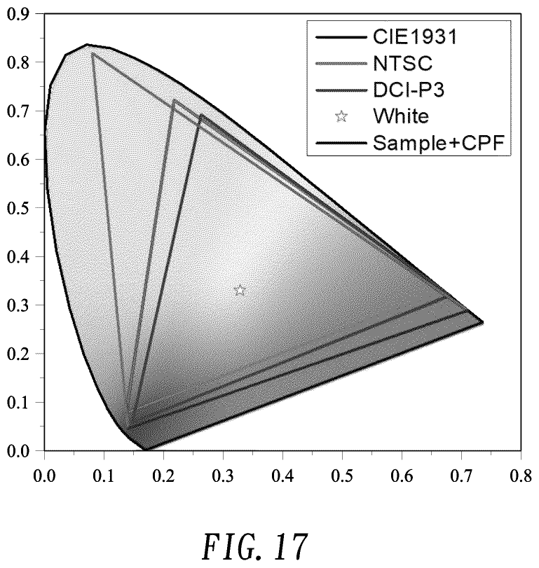

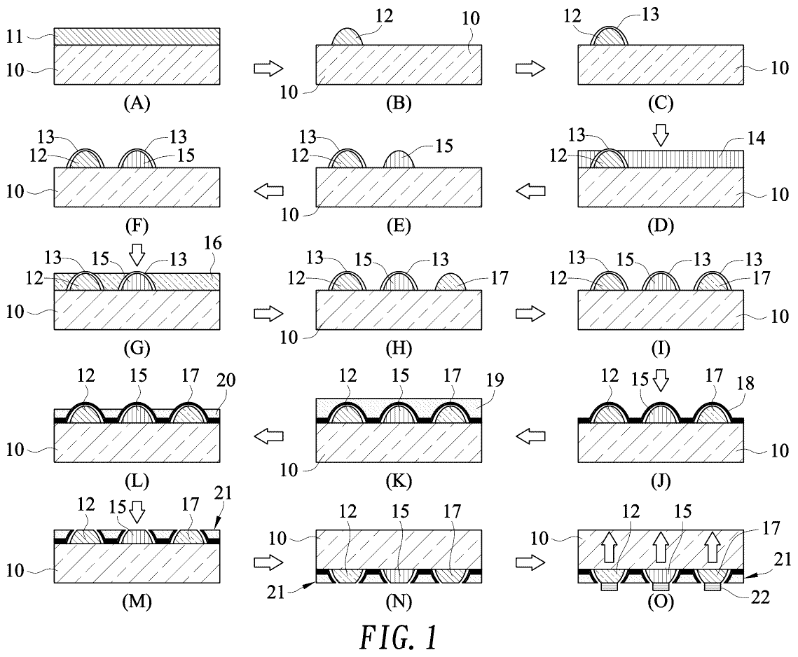

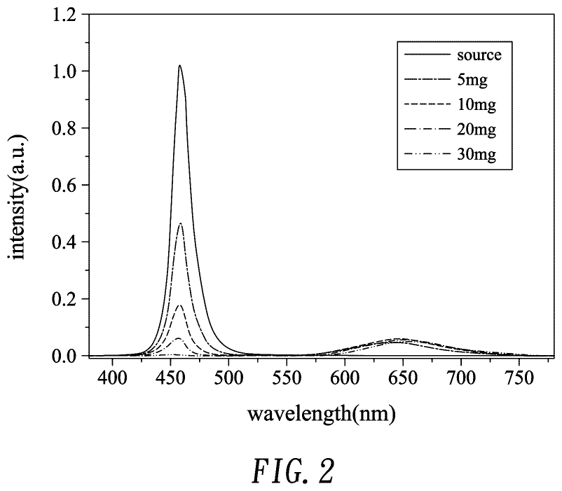

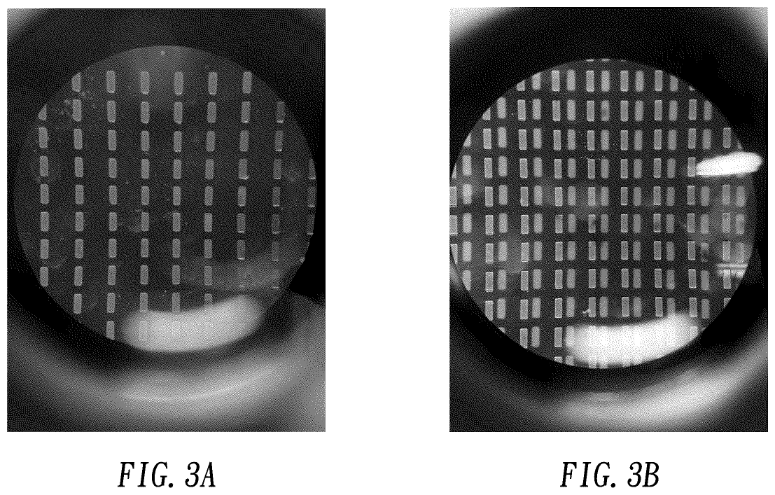

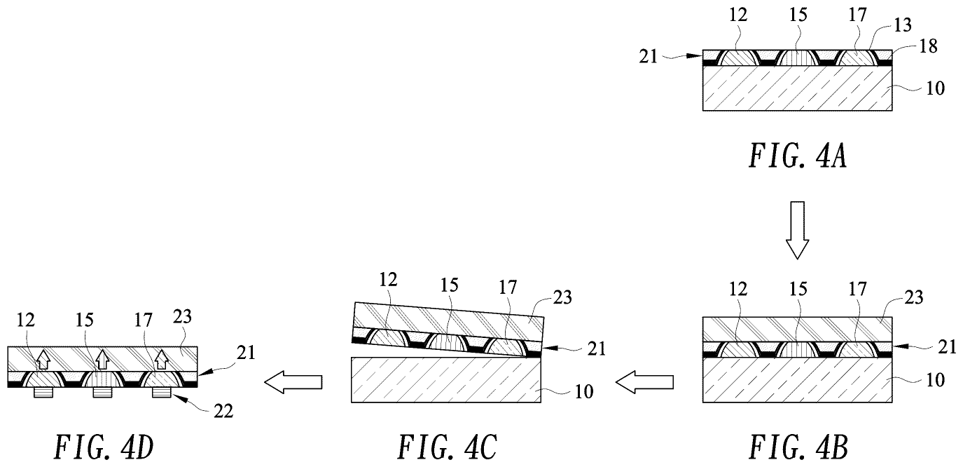

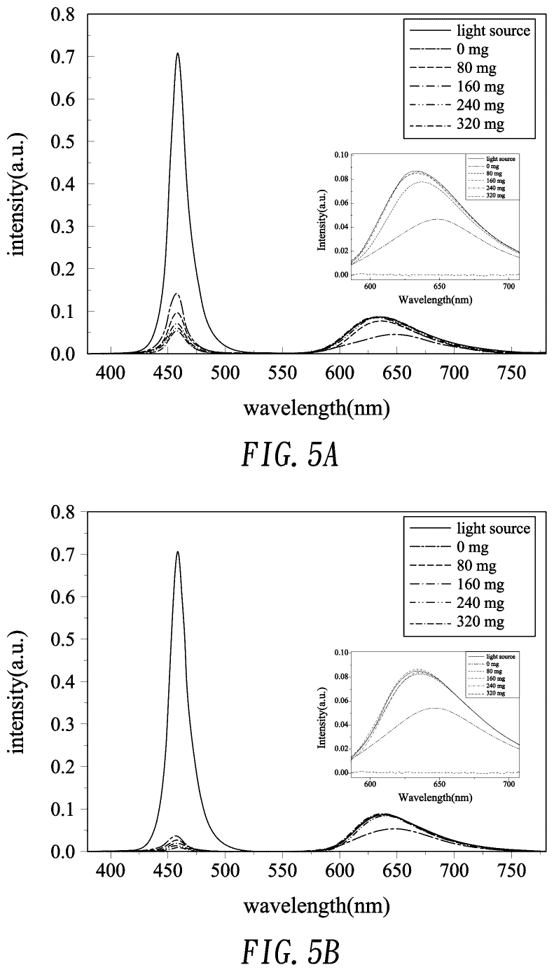

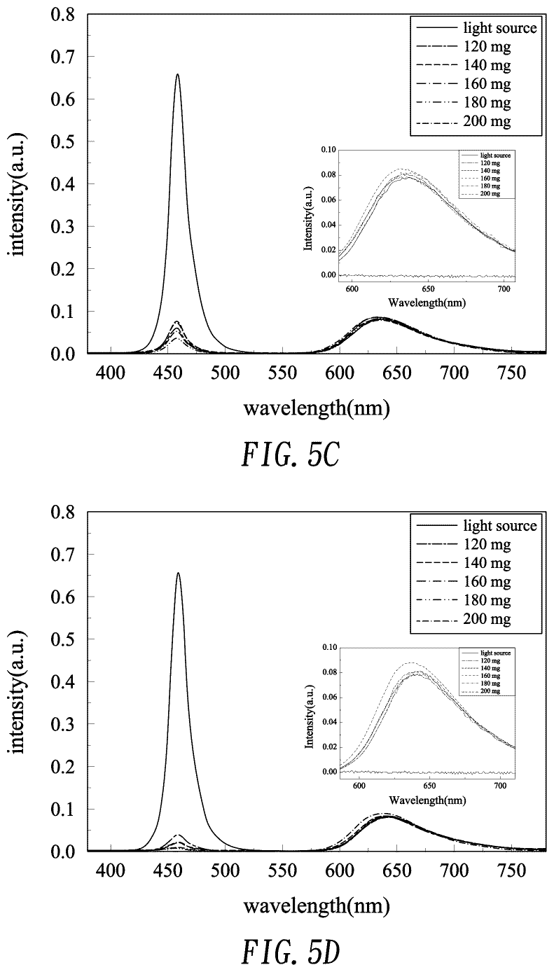

In some examples, five second color conversion solutions are prepared with DCJTB phosphor of 10 mg, photoresist (EOC170) of 5 ml, and TiO₂ nanoparticles having size of 15 nm and weight of 0, 80, 160, 240, and 320 mg respectively. FIG. 5A shows photoluminescence (PL) spectra of five color conversion films, and FIG. 5B shows photoluminescence (PL) spectra of the respective superimposed color conversion films.

Table 2 lists optical properties of the above five color conversion films and the respective superimposed color conversion films.

TABLE 2

| | | | | | | superposition of two same | | | | |
|---|---|---|---|---|---|---|---|---|---|---|
| | one color conversion film | | | | | color conversion films | | | | |
| TiO₂ (mg) | 0 | 80 | 160 | 240 | 320 | 0 | 80 | 160 | 240 | 320 |
| quantum yield | 45.6 | 64.1 | 68.5 | 67.3 | 67.0 | 45.3 | 62.8 | 64.5 | 61.9 | 62.4 |
| (%) | | | | | | | | | | |
| blue light | 80.9 | 86.5 | 89.8 | 91.7 | 92.1 | 94.5 | 95.7 | 96.7 | 97.6 | 98.2 |
| absorbance (%) | | | | | | | | | | |
| conversion | 36.9 | 55.4 | 61.5 | 61.7 | 61.7 | 42.8 | 60.1 | 62.4 | 60.4 | 61.3 |
| efficiency(%) | | | | | | | | | | |
| absorbance peak | 458 | 458 | 458 | 458 | 458 | 457 | 458 | 458 | 458 | 458 |
| (nm) | | | | | | | | | | |
| emission peak | 647 | 636 | 632 | 632 | 632 | 649 | 639 | 636 | 638 | 636 |
| (nm) | | | | | | | | | | |

In some examples, five second color conversion solutions are prepared with DCJTB phosphor of 10 mg, photoresist (EOC170) of 5 ml, and TiO₂ nanoparticles having size of 15 nm and weight of 120, 140, 160, 180, and 200 mg respectively. FIG. 5C shows photoluminescence (PL) spectra of five color conversion films, and FIG. 5D shows photoluminescence (PL) spectra of the respective superimposed color conversion films.

Table 3 lists optical properties of the above five color conversion films and the respective superimposed color conversion films.

TABLE 3

| | | | | | | superposition of two same | | | | |
|---|---|---|---|---|---|---|---|---|---|---|
| | one color conversion film | | | | | color conversion films | | | | |
| TiO₂ (mg) | 120 | 140 | 160 | 180 | 200 | 120 | 140 | 160 | 180 | 200 |
| quantum yield | 69.8 | 70.9 | 68.5 | 68.7 | 68.1 | 64.3 | 64.5 | 64.5 | 62.8 | 62.2 |
| (%) | | | | | | | | | | |
| blue light | 90.6 | 88.0 | 89.8 | 93.7 | 91.2 | 93.1 | 96.0 | 96.7 | 97.9 | 97.7 |
| absorbance (%) | | | | | | | | | | |
| conversion | 63.2 | 62.4 | 61.5 | 64.4 | 62.1 | 59.9 | 61.9 | 62.4 | 61.5 | 60.8 |
| efficiency(%) | | | | | | | | | | |
| absorbance peak | 458 | 458 | 458 | 458 | 458 | 459 | 458 | 458 | 458 | 458 |
| (nm) | | | | | | | | | | |
| emission peak | 635 | 632 | 632 | 632 | 632 | 638 | 640 | 636 | 642 | 641 |
| (nm) | | | | | | | | | | |

According to Table 2 and Table 3, the sample with TiO₂ nanoparticles of 140 mg reveals best quantum yield of 70.9%. The sample with 180 mg of TiO₂ nanoparticles reveals the highest blue light absorbance of 93.7% and the highest conversion efficiency of 64.4%.

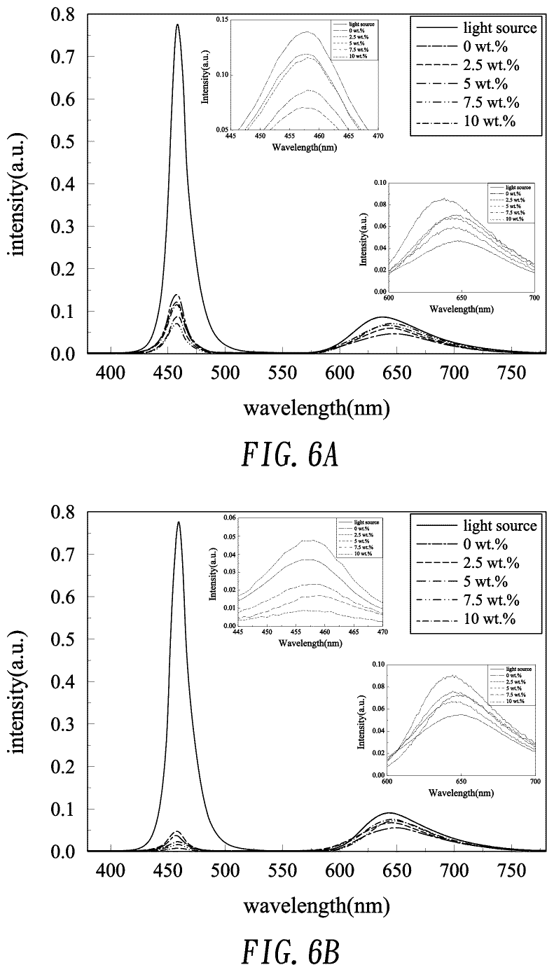

In some examples, five second color conversion solutions are prepared with DCJTB phosphor of 10 mg, photoresist (EOC170) of 5 ml, and SiO₂ nanoparticles with composition of 0, 2.5, 5, 7.5, and 10 wt % respectively. FIG. 6A shows photoluminescence (PL) spectra of five color conversion films, and FIG. 6B shows photoluminescence (PL) spectra of the respective superimposed color conversion films. The composition of nanoparticles is equal to the weight of the nanoparticles divided by the total weight of the color conversion solution—the weight of the photoresist plus the weight of the organic phosphor plus the weight of the nanoparticles. Table 4 lists optical properties of the above five color conversion films and the respective superimposed color conversion films.

TABLE 4

| | | | | | | superposition of two same | | | | |
|---|---|---|---|---|---|---|---|---|---|---|
| | single color conversion film | | | | | color conversion films | | | | |
| SiO₂ (wt %) | 0 | 2.5 | 5 | 7.5 | 10 | 0 | 2.5 | 5 | 7.5 | 10 |
| quantum yield | 45.6 | 51.8 | 59.0 | 56.5 | 68.9 | 45.3 | 51.7 | 55.3 | 52.0 | 61.9 |
| (%) | | | | | | | | | | |
| blue light | 80.9 | 84.2 | 84.3 | 90.2 | 88.1 | 94.5 | 93.5 | 96.7 | 97.6 | 98.8 |
| absorbance (%) | | | | | | | | | | |
| conversion | 36.9 | 43.6 | 49.7 | 51.0 | 60.7 | 42.8 | 48.3 | 53.5 | 50.8 | 61.2 |
| efficiency(%) | | | | | | | | | | |
| absorbance peak | 458 | 458 | 458 | 458 | 457 | 457 | 458 | 459 | 459 | 457 |
| (nm) | | | | | | | | | | |
| emission peak | 647 | 644 | 643 | 644 | 638 | 649 | 646 | 644 | 647 | 644 |
| (nm) | | | | | | | | | | |

According to Table 4, the single color conversion film with 10 wt % SiO₂ nanoparticles reveals the highest quantum yield of 68.9%, the blue light absorbance of 88.1%, and the conversion efficiency of 60.7%, and the emission peak is within the red light transmission band of the color purifying as described above.

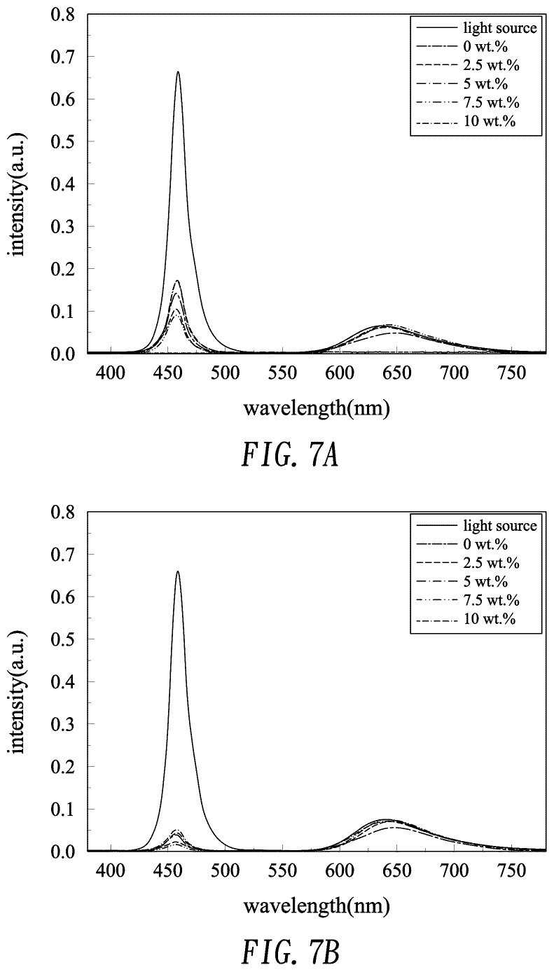

In some examples, five second color conversion solutions are prepared with DCJTB phosphor of 10 mg, photoresist (EOC170) of 5 ml, and ZnO nanoparticles having size of 100 nm and composition of 0, 2.5, 5, 7.5, and 10 wt % respectively. FIG. 7A shows photoluminescence (PL) spectra of five color conversion films, and FIG. 7B shows photoluminescence (PL) spectra of the respective superimposed color conversion films. Table 5 lists optical properties of the above five color conversion films and the respective superimposed color conversion films.

TABLE 5

| | | | | | | superposition of two same | | | | |
|---|---|---|---|---|---|---|---|---|---|---|
| | single color conversion film | | | | | color conversion films | | | | |
| ZnO (wt %) | 0 | 2.5 | 5 | 7.5 | 10 | 0 | 2.5 | 5 | 7.5 | 10 |
| quantum yield | 45.6 | 60.1 | 67.4 | 64.8 | 70.6 | 45.3 | 57.4 | 62.9 | 62.7 | 65.9 |
| (%) | | | | | | | | | | |
| blue light | 80.9 | 84.6 | 75.1 | 86.6 | 74.9 | 94.5 | 96.0 | 91.8 | 96.7 | 93.0 |
| absorbance (%) | | | | | | | | | | |
| conversion | 36.9 | 50.8 | 50.6 | 56.1 | 52.9 | 42.8 | 55.1 | 57.7 | 60.6 | 61.3 |
| efficiency(%) | | | | | | | | | | |
| absorbance peak | 458 | 458 | 458 | 458 | 459 | 457 | 457 | 457 | 457 | 457 |
| (nm) | | | | | | | | | | |
| emission peak | 647 | 639 | 638 | 644 | 636 | 649 | 646 | 640 | 643 | 636 |
| (nm) | | | | | | | | | | |

As shown Table 5, the emission peak of the color conversion film with 100 nm ZnO nanoparticles blueshifts from 647 nm to 636 nm, and the quantum yield increases from 45.6% to 70.6%, compared to the film with SiO₂ nanoparticles.

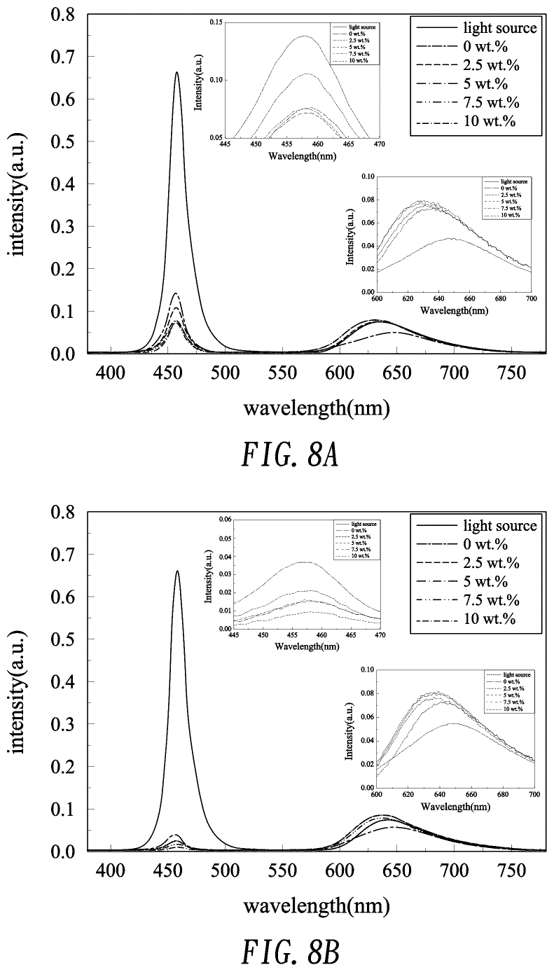

In some examples, five second color conversion solutions are prepared with DCJTB phosphor of 10 mg, photoresist (EOC170) of 5 ml, and TiO₂ nanoparticles having size of 170 nm and composition of 0, 2.5, 5, 7.5, and 10 wt % respectively. FIG. 8A shows photoluminescence (PL) spectra of five color conversion films, and FIG. 8B shows photoluminescence (PL) spectra of the respective superimposed color conversion films. Table 6 lists optical properties of the above five color conversion films and the respective superimposed color conversion films.

TABLE 6

| | | | | | | superposition of two same | | | | |
|---|---|---|---|---|---|---|---|---|---|---|
| | single color conversion film | | | | | color conversion films | | | | |
| TiO₂ (wt %) | 0 | 2.5 | 5 | 7.5 | 10 | 0 | 2.5 | 5 | 7.5 | 10 |
| quantum yield | 45.6 | 68.3 | 69.9 | 67.8 | 64.1 | 45.3 | 63.3 | 61.6 | 59.5 | 55.3 |
| (%) | | | | | | | | | | |
| blue light | 80.9 | 84.6 | 88.8 | 89.4 | 88.5 | 94.5 | 96.7 | 97.4 | 97.4 | 98.3 |
| absorbance (%) | | | | | | | | | | |
| conversion | 36.9 | 57.8 | 62.1 | 60.6 | 56.7 | 42.8 | 61.2 | 60.0 | 58.0 | 54.4 |
| efficiency(%) | | | | | | | | | | |
| absorbance peak | 458 | 458 | 458 | 458 | 459 | 457 | 458 | 457 | 458 | 458 |
| (nm) | | | | | | | | | | |
| emission peak | 647 | 631 | 630 | 628 | 636 | 649 | 639 | 636 | 636 | 640 |
| (nm) | | | | | | | | | | |

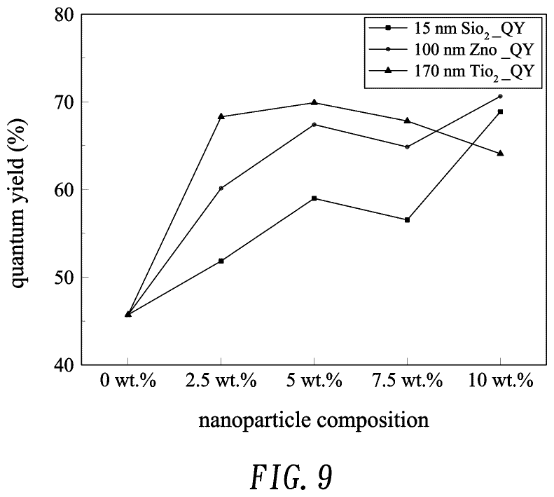

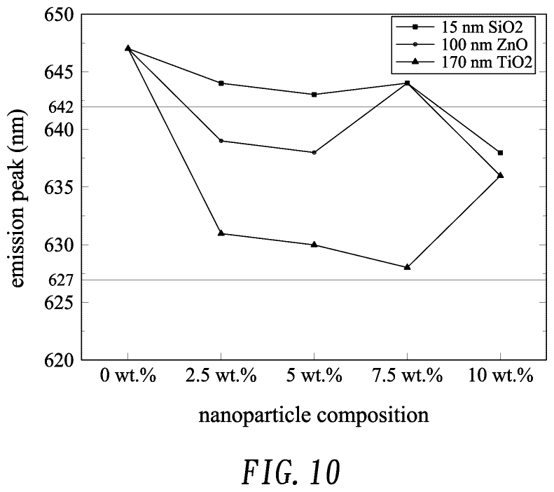

FIG. 9 show line charts of nanoparticle composition (wt %) versus quantum yield (%) of film for different nanoparticles. FIG. 10 show line charts of nanoparticle composition (wt %) versus emission peak of film for different nanoparticles. The film doped with 170 nm-sized TiO₂ nanoparticles reveals significant effect. In which the quantum yield reaches 69.9%, and conversion efficiency reaches the highest 68.1%. In addition, the film doped with 170 nm-sized TiO₂ nanoparticles cause the emission peak to be blue-shifted the most compared to the films doped with other two nanoparticles.

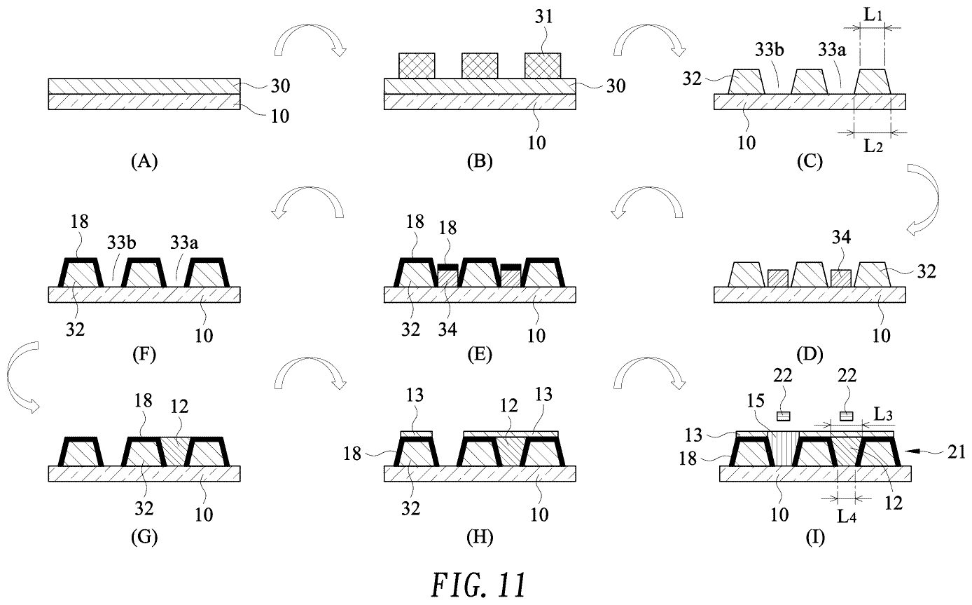

FIG. 11 is a schematic diagram showing a method for fabricating a color conversion film array in accordance with another embodiment of the present invention. As shown in step (A), a bottom layer 30, such as an insulating layer or an oxide layer, e.g., SiO₂, is deposited over the substrate 10. The bottom layer 30, with thickness of about 3 μm, may be deposited by, e.g., plasma enhanced chemical vapor deposition (PECVD). As shown in step (B), a first photoresist layer is deposited on the bottom layer 30, and then is exposed and developed to form a patterned first photoresist layer 31. As shown in step (C), by employing the patterned first photoresist layer 31 as a mask, the bottom layer 30 is etched by, e.g., reactive ion etching (RIE) to form a microstructure array 32. In the exemplary embodiment, the microstructure array 32 is a trapezoidal structure array, in which the length L1 of an upper base is less than the length L2 of a lower base of each trapezoidal structure. And a groove, e.g., a first groove 33a, a second groove 33b, and a third groove (not shown), is formed between every two adjacent trapezoidal microstructures. As shown in step (D), a second photoresist layer, such as NR9, is deposited and then exposed and developed to form a patterned second photoresist layer 34 that partially fills the all grooves (33a/33b and etc.). As shown in step (E), a shielding layer 18 is deposited on the surface of the microstructure array 32 and the patterned second photoresist layer 34. The shielding layer 18 is usually made of a metal with high reflectivity, such as chromium. The shielding layer 18 may also be made of silver or black photoresist. As shown in step (F), a solvent, such as acetone, is used to lift-off the photoresist (NR9) to expose all grooves (33a/33b and etc.). As shown in step (G), using a spin coating method similar to that previously described to deposit a first color conversion solution and hence form a first color conversion film, which is then exposed and developed to form a first color conversion sub-film array 12 filling all the first grooves 33a. A surface modification layer may be deposited prior to depositing the first color conversion film. As shown in step (H), a protective layer 13, such as silicon dioxide with a thickness of 100 nm, may be deposited on the upper surface of the first color conversion sub-film array 12 and the microstructure array 32. As shown in step (I), using the spin coating method similar to that previously described to deposit a second color conversion solution and hence form a second color conversion film, which is then exposed and developed to form a second color conversion sub-film array 15 filling all the second grooves 33b and hence form a color conversion film array 21. In one embodiment, the color conversion film array 21 further includes depositing a transparent solution using a spin coating method similar to that previously described to form a transparent film, which is then exposed and developed to form a transparent sub-film array filling third grooves (not shown). As shown in step (I), the color conversion film array 21 is aligned with a micro-LED array 22 to form a micro-LED display. As shown in step (I), in the exemplary embodiment, the first color conversion sub-film array 12 and the second color conversion sub-film array 15 both are trapezoidal structure array, in which the length L3 of an upper base is greater than the length L4 of a lower base of each trapezoidal structure. The light from the micro-LED array 22 strikes an incident surface having the upper base and outs from a light-emitting surface having the lower base. The area of the incident surface is greater than the area of the light-emitting surface. Compared with the embodiment described in FIG. 1, the light emitted from the color conversion film array 21 of the exemplary embodiment is more concentrated and collimated.

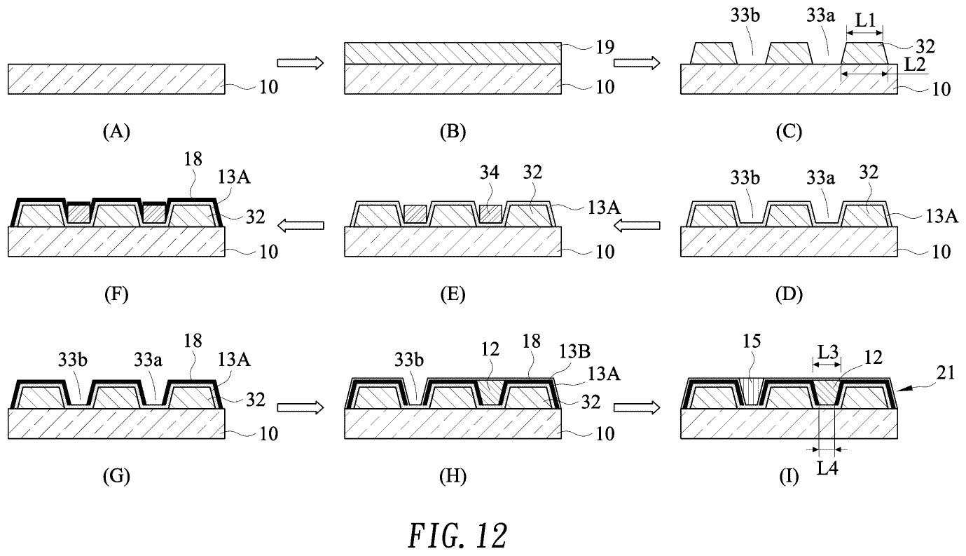

FIG. 12 is a schematic diagram showing a method for fabricating a color conversion film array in accordance with another embodiment of the present invention. As shown in step (A), a substrate 10, such as a transparent or glass substrate is provided. As shown in step (B), a first photoresist layer is deposited on the bottom layer 30, and then is exposed and developed to form a microstructure array 32 (also referred as a patterned first photoresist layer). In the exemplary embodiment, the microstructure array 32 is a trapezoidal structure array, in which the length L1 of an upper base is less than the length L2 of a lower base of each trapezoidal structure. And a groove, e.g., a first groove 33a, a second groove 33b, and a third groove (not shown), is formed between every two adjacent trapezoidal microstructures. As shown in step (D), a first protective layer 13A, such as silicon dioxide, is deposited to cover the microstructure array 32. As shown in step (E), a second photoresist layer, such as NR9, is deposited and exposed and developed to form a patterned second photoresist layer 34 that partially fills all grooves (33a/33b and etc.). As shown in step (F), a shielding layer 18 is deposited to cover the microstructure array 32 and the patterned second photoresist layer 34. The shielding layer 18 is usually made of a metal with high reflectivity, such as chromium. The shielding layer 18 may also be made of silver or black photoresist. As shown in step (F), a solvent, such as acetone, is used to lift-off the photoresist (NR9) to expose all grooves (33a/33b and etc.).

As shown in step (G), using a spin coating method similar to that previously described to deposit a first color conversion solution and hence form a first color conversion film, which is then exposed and developed to form a first color conversion sub-film array 12 filling all the first grooves 33a. As shown in step (H), a second protective layer 13B, such as silicon dioxide, may be deposited to cover the first color conversion sub-film array 12 and the microstructure array 32. As shown in step (I), using the spin coating method similar to that previously described to deposit a second color conversion solution and hence form a second color conversion film, which is then exposed and developed to form a second color conversion sub-film array 15 filling all the second grooves 33b and hence form a color conversion film array 21. In one embodiment, the color conversion film array 21 further includes depositing a transparent solution using the spin coating method similar to that previously described to form a transparent film, which is then exposed and developed to form a transparent sub-film array filling third grooves (not shown). As shown in step (I), in the exemplary embodiment, the first color conversion sub-film array 12 and the second color conversion sub-film array 15 both are trapezoidal structure array, in which the length L3 of an upper base is greater than the length L4 of a lower base of each trapezoidal structure. The light from the micro-LED array 22 strikes an incident surface having the upper base and outs from a light-emitting surface having the lower base. The area of the incident surface is greater than the area of the light-emitting surface.

The pixel height of the color conversion film array 21 produced by the method described in FIG. 11 and FIG. 12 can be between 2.4 μm and 2.6 μm, thereby optimizing the Pixel aspect ratio. This optimized Pixel aspect ratio not only strengthens the pixels in the color conversion film array, but also comes with other benefits—e.g., minimizing color crosstalk between neighboring pixels, and greatly improving the yield of subsequent manufacturing steps.

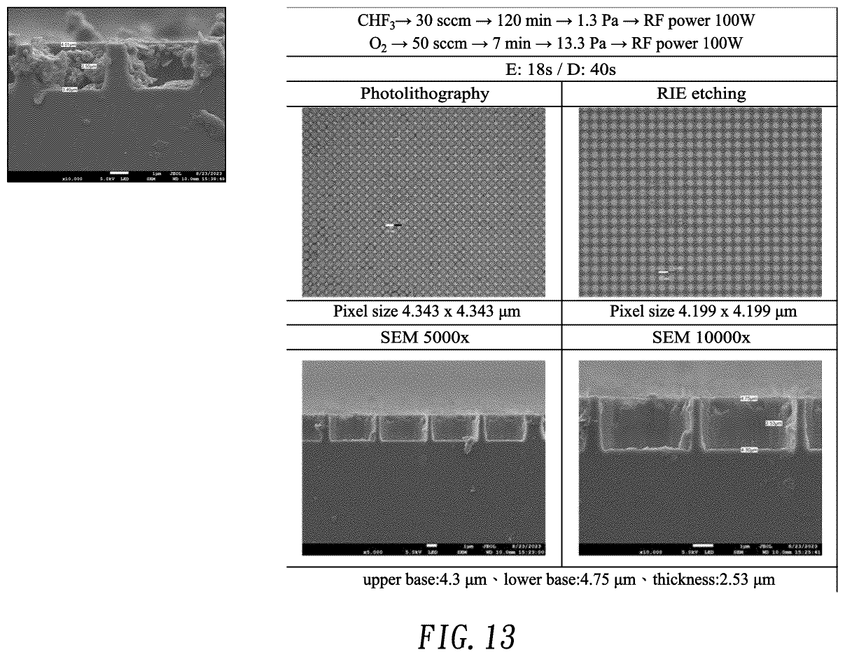

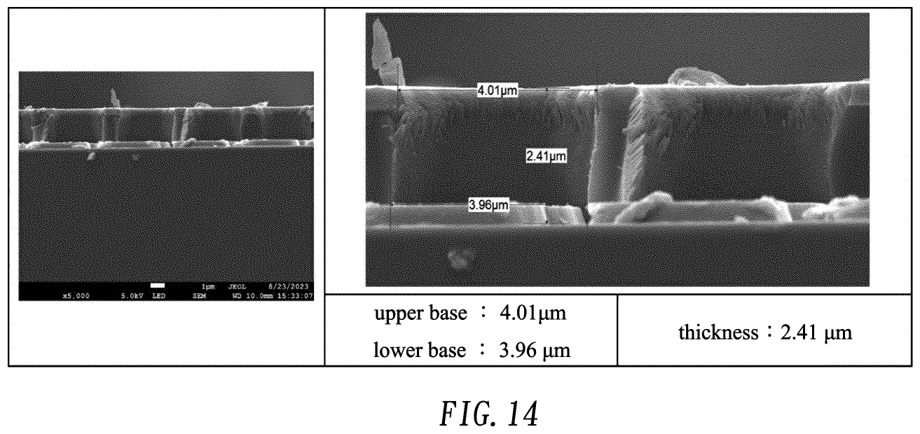

FIG. 13 is a photo of a trapezoidal microstructure array produced by reactive ion etching according to the method described in FIG. 11, with exposure for 18 s and development for 40 s. FIG. 14 is a photo of a trapezoidal microstructure array produced according to the method described in FIG. 12, with exposure for 18 s and development for 55 s.

In the following embodiments of the present disclosure, further improvements are made to the previously filed U.S. patent Pub. No. US20220209074. The contents of the indicated patent are incorporated and deemed to form part of the specification of this invention. In the following embodiments, both the first color conversion solution and the second color conversion solution (described in FIG. 1) include: an organic fluorescent material, a polymer, a solvent, and nanoparticles (NPs) with size of 1 nm to 100 nm. The nanoparticles may be spherical or rod-shaped, or have form of other shapes. In some embodiments, the first and/or second color conversion solution contains nanoparticles with varied shapes. The nanoparticles is used to lengthen the optical path length (also referred to as the ‘optical path’ for brevity) of the light (such as blue light) in the color conversion sub-film, which is emitted by the micro-light emitting diode array, thereby increasing the light absorption of the color conversion sub-film. In some embodiments, the nanoparticles are inorganic nanoparticles, including, e.g., TiO₂, SiO₂, and/or ZnO nanoparticles. In some embodiments, the nanoparticles comprise silver nanoparticles (which may contain silver oxide). In some examples, the nanoparticles are made of TiO₂ with particle size of 15 nm, 170 nm, or 240 nm.

An example of fabricating a second color conversion solution:

(1) adding 167 mg of TiO₂ nanoparticles with size of 240 nm in a sample jar; (2) adding 15 mg of DCJTB phosphor into the sample jar; (3) adding 10 ml of THF (tetrahydrofuran) as a solvent and putting a magnetic stirrer into the sample tank; (4) placing the sample jar on a hotplate and stirring the solution for 30 minutes at a temperature of 45° C. and a speed of 450 rpm; (5) adding 1.5 g of PVB (polyvinyl butyral) and dissolve it in the sample jar; (6) stirring the solution by the hotplate at 45° C. with a speed of 450 rpm for 24 hours (overnight).

In addition, an example of fabricating a first color conversion solution is the same as fabricating the second color conversion solution. The difference is that the DCJTB phosphor in the second color conversion solution is replaced by Coumarin6 phosphor.

An example of fabricating a second color conversion film: placing the prepared second color conversion solution on a vacuum plate for evacuation for 20 minutes; placing a glass substrate on a base of the spin coater and holding the glass substrate by a vacuum chunk, then loading the prepared second color conversion solution evenly on the glass substrate with a dropper; spin coating the second color conversion solution with an initial speed of 2500 rpm for 10 seconds, then a terminal speed of 6000 rpm for 30 seconds, then breaking the vacuum and removing the glass substrate; placing the glass substrate on the hotplate and heating it at 90° C. for 30 minutes, and then removing the glass substrate.

In some examples, five color conversion films are prepared by a DCJTB phosphor of 4.5 mg, PVB of 1.5 g, and 240 nm-sized TiO₂ nanoparticles with composition of 5, 10, 15, 20, 25 wt %, respectively. Where the composition of nanoparticles (wt %)=weight of nanoparticles/(weight of nanoparticles+weight of PVB+weight of organic fluorescent material). The prepared five red color conversion films are then put into an integrating sphere measurement system for measurement. The system employs a blue LED to emit an excitation light with a wavelength of 460 nm. The quantum yield, blue light absorbance, peak wavelength, etc. of the color conversion films are calculated respectively by the excitation spectrum and emission spectra of the five color conversion films, as list in Table 7.

TABLE 7

| | peak | | blue light |
|---|---|---|---|
| nanoparticle | wave- | quantum | absorbance |
| composition(wt %) | length(nm) | yield (%) | (%) |
| 0 | 644 | 50.4 | 37.8 |
| 5 | 626 | 60.9 | 30.7 |
| 10 | 622 | 62.1 | 43.2 |
| 15 | 619 | 61.1 | 46.8 |
| 20 | 619 | 60.3 | 56.6 |
| 25 | 613 | 59.5 | 59.9 |

According to Table 7, the film with TiO₂ nanoparticles of 10% reveals best quantum yield of 62.1%, which means that this color conversion film converts into more of red light under the same blue light absorption. In addition, blue light absorbance is significantly improved to 43.2%.

In some examples, five second color conversion solutions and films are prepared with 240 nm-sized TiO₂ nanoparticles of 10 wt %, PVB of 1.5 g, and DCJTB phosphor with weight 0, 4.5, 10, 15, 20, 25 mg, respectively. Table 8 lists optical properties of the prepared five red-color conversion films

TABLE 8

| | peak | | blue light | conversion |
|---|---|---|---|---|
| DCJTB | wave- | quantum | absorbance | efficiency |
| weight(mg) | length(nm) | yield(%) | (%) | (%) |
| 0 | x | 0 | 31.0 | 0 |
| 4.5 | 622 | 62.1 | 43.2 | 26.6 |
| 10 | 623 | 55.7 | 89.1 | 49.6 |
| 15 | 628 | 55.2 | 94.9 | 52.4 |
| 20 | 628 | 54.7 | 94.7 | 51.8 |
| 25 | 632 | 50.8 | 96.3 | 48.9 |

As shown in Table 8, the conversion efficiency increases with the amount of DCJTB phosphor, reaching the highest 52.4% as DCJTB phosphor of 15 mg, and then decreases. The peak wavelength of the color conversion film with the highest efficiency is 628 nm. In some examples, the peak wavelength of the first color conversion film is between 627 and 642 nm.

In some examples, in order to produce the size of pixels, the thickness of the color conversion film needs to be reduced to improve the pixel aspect ratio and reduce the crosstalk between neighboring pixels. In some experiments, this is made by increasing the speed (2500, 4000, 6000 rpm) of spin coating the second color conversion solution, and/or increasing the volume (10, 12, 14 mL) of solvent (such as THE, tetrahydrofuran) in the second color conversion solution.

Table 9 lists the thickness and properties of the color conversion films made by 10 mL of solvent THF and different initial speeds of spin coating.

TABLE 9

| | | | blue light | conversion |
|---|---|---|---|---|
| initial | thickness | quantum | absorbance | efficiency |
| speed(rpm) | (μm) | yield(%) | (%) | (%) |
| 2500 | 8.273 | 60.1 | 87.7 | 52.7 |
| 4000 | 7.730 | 60.9 | 84.0 | 51.1 |
| 6000 | 7.650 | 61.5 | 77.7 | 47.8 |

Table 10 lists the thickness and properties of the color conversion films made by 12 mL of solvent THF and different initial speeds of spin coating.

TABLE 10

| | | | blue light | conversion |
|---|---|---|---|---|
| initial | thickness | quantum | absorbance | efficiency |
| speed(rpm) | (μm) | yield(%) | (%) | (%) |
| 2500 | 7.050 | 61.2 | 82.2 | 50.3 |
| 4000 | 4.437 | 60.9 | 77.7 | 47.3 |
| 6000 | 4.130 | 62.9 | 64.4 | 40.5 |

Table 11 lists the thickness and properties of the color conversion films made by 14 mL of solvent THF and different initial speeds of spin coating.

TABLE 11

| | | | blue light | conversion |
|---|---|---|---|---|
| initial | thickness | quantum | absorbance | efficiency |
| speed(rpm) | (μm) | yield(%) | (%) | (%) |
| 2500 | 3.956 | 63.3 | 64.2 | 40.6 |
| 4000 | 3.094 | 63.8 | 58.3 | 37.2 |
| 6000 | 2.906 | 64.2 | 52.7 | 33.8 |

It can be seen from Tables 9-11, by increasing the spin coating speed from 2500 rpm to 6000 rpm and increasing the volume of solvent from 10 mL to 14 mL, the thickness of the second color conversion film is reduced from 8 μm to 3 μm, while the quantum yield increased from 60.1% to 64.2%.

In one embodiment, a second color conversion film is prepared by the above second color conversion solution, and the prepared film is combined with a color-purifying film (CPF) 23 provided by the team of Professor Zhi Ting Ye of National Chung Cheng University. The color-purifying film 23 allows one or more specific wavebands of light to transmit. In some embodiments, the color-purifying film 23 merely allows red light and green light wavelength bands to pass through. In the exemplary embodiment, the transmittable wavelength bands of the color-purifying film 23 include red light 627˜642 nm and green light 514˜528 nm. The full width at half maximum (FWHM) of emission spectrum of the color conversion film combined with the color-purifying film can be greatly reduced to 18˜22 nm, thereby improving the color purity of light emission. In addition, the color-purifying film further reflects the wavelength band that is non-transmitted (such as blue light) back to the color conversion film array 21 so that it is converted again, thereby improving the conversion efficiency.

Table 12 shows properties of the color-purifying film respectively combined with the second color conversion films made by different spin coating speeds. The table further lists absorbance and peak wavelength of the second color conversion films without combined the CPF. All samples were measured on a silver-plated stage.

TABLE 12

| | | | | peak | | | |
|---|---|---|---|---|---|---|---|
| rotation | | absorbance(%) | | wavelength(nm) | | | |
| speed | quantum | w/o | With | w/o | With | conversion | thickness |
| (rpm) | yield(%) | CPF | CPF | CPF | CPF | efficiency(%) | (μm) |
| 2500 | 75.8 | 64.1 | 99.60 | 626 | 637 | 75.5 | 3.96 |
| 4000 | 77.7 | 56.2 | 99.48 | 623 | 640 | 77.3 | 3.09 |
| 6000 | 78.8 | 52.7 | 99.64 | 624 | 639 | 78.5 | 2.91 |

As shown in Table 12, the quantum yield of the color conversion film increases as the thickness decreases, and the absorbance also decreases if not combined with the CPF. While the absorbance of the color conversion film is maintained if combined with the CPF, and the conversion efficiency reaches 78.5% as the film thickness is reduced to 2.91 μm.

In some embodiments, each of the first color conversion film and the second color conversion film, as well as the subsequently fabricated patterned first color conversion film and patterned second color conversion film, includes two layers: an upper layer and a lower layer. The upper layer includes nanoparticles, and the lower layer does not. In a specific embodiment, the two-layered film is made by spin coatings twice. Taking the first color conversion film as an example, a first color conversion solution with nanoparticles and a first color conversion solution without nanoparticles are respectively prepared, and then the first color conversion solution without nanoparticles is spin-coated and then heated to form a lower layer. After that, the first color conversion solution with nanoparticles is spin-coated and heated to form an upper layer. A second color conversion film having an upper layer and a lower layer can be produced using the same method.

For example, a second color conversion solution is prepared by 167 mg (10 wt %) of 240 nm-sized TiO₂ nanoparticles, 16 mL of solvent THF (tetrahydrofuran), and other same compositions as the previously prepared second color conversion solution. In addition, another second color conversion solution without nanoparticles is prepared with the same composition except the nanoparticles. The second color conversion film is made by spin coatings two times. Both spin coatings are performed with 7000 rpm for 40 seconds.

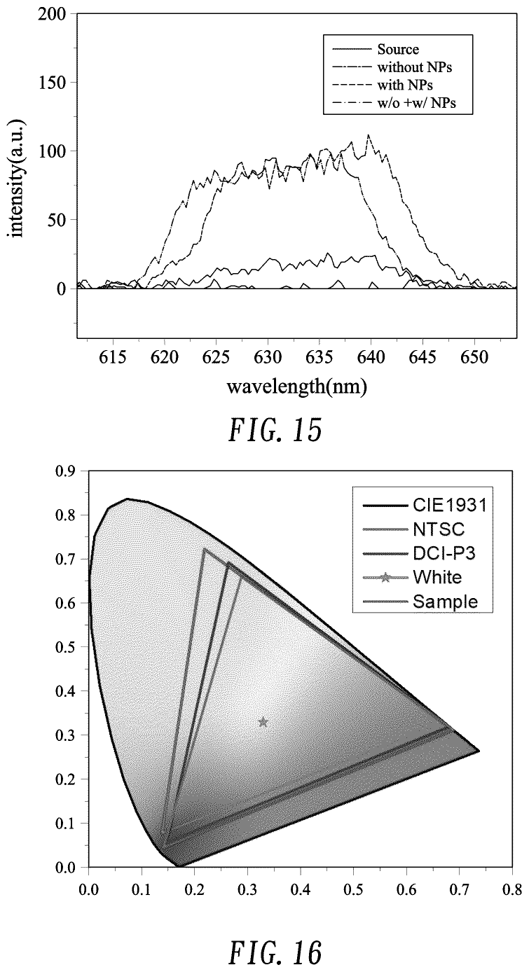

FIG. 15 shows PL spectra of three second color conversion films, in which one is composed of an upper layer and a lower layer (w/o+w/NPs), another is single-layered film without nanoparticles (without NPs), and the third is single-layered film with nanoparticles (with NPs).

Table 13 lists the properties of the three second color conversion films combined with a color-purifying film (CPF).

TABLE 13

| | | absorbance(%) | | conversion | |
|---|---|---|---|---|---|
| | quantum | w/o | with | efficiency | thickness |
| Films | yield(%) | CPF | CPF | (%) | (μm) |
| w/o NPs | 91.8 | 11.2 | 99.0 | 90.9 | 2.44 |
| with NPs | 79.1 | 49.0 | 99.6 | 78.8 | 2.61 |
| w/NPs(upper | 81.9 | 54.5 | 99.7 | 81.7 | 2.70 |
| layer) + | | | | | |
| w/o NPs(lower | | | | | |
| layer) | | | | | |

The color conversion film with upper and lower layers can avoid the accumulation of nanoparticles during RIE etching. In addition, it can be seen from Table 13 that the color conversion film with upper and lower layers reveals higher quantum yield and conversion efficiency. Although the color conversion film without nanoparticles reveals high quantum yield, absorbance, and conversion efficiency, its emission spectrum reveals a low emission intensity and a poor color conversion.

FIG. 16 shows CIE 1931 chromaticity diagram of combining a first color conversion film, a second color conversion film, and a transparent film produced by the present invention, where a blue LED with emission wavelength of 460 nm is used to excite the films.

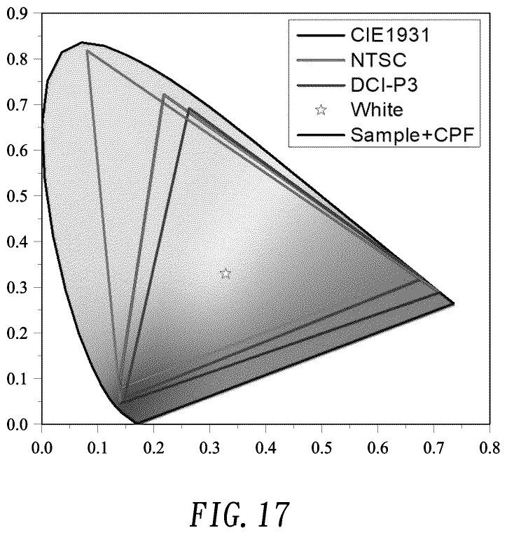

FIG. 17 shows CIE 1931 chromaticity diagram of combining a first color conversion film, a second color conversion film, a transparent film, and a color-purifying film of the present invention, where a blue LED with emission wavelength of 460 nm is used to excite the films.

Table 14 lists the CIE 1931 coordinates obtained from FIGS. 16 and 17.

TABLE 14

CIE 1931 coordinates

| | first color | second color | transparent |
|---|---|---|---|
| | conversion film | conversion film | film |
| w/o CPF | 0.671, 0.328 | 0.285, 0.662 | 0.144, 0.029 |
| with CPF | 0.707, 0.292 | 0.074, 0.833 | 0.144, 0.029 |

Then, DCI-P3, a color space defined by the Digital Cinema Initiative is employed to calculate color gamut and color coverage of the produced color conversion films. The results are listed in Table 15.

TABLE 15

| | w/o CPF | with CPF |
|---|---|---|
| DCI-P3 color gamut (%) | 96.43 | 148.25 |
| DCI-P3 color coverage (%) | 92.96 | 95.64 |

In the above embodiments, neither the first nor the second color conversion solution contains a photoresist. In some embodiments, after forming the first color conversion film, a silicon dioxide layer and then a photoresist layer are deposited on its surface. Then, the photoresist layer is exposed and developed to form a patterned photoresist layer. Then, reactive ion etching (RIE) is employed by using CHF₃ to etch the silicon dioxide layer to form a patterned silicon dioxide layer. Then, O₂ is used to etch the patterned photoresist layer and the first color conversion film. After removing the patterned silicon dioxide layer, a patterned first color conversion film can be obtained. A patterned second color conversion film can also be produced using the method described above. The order of producing the patterned first color conversion film and the patterned first color conversion film may be interchanged.

As shown in FIGS. 15-17 and Tables 7-15, after being doped with nanoparticles, the previously proposed color conversion films by the applicant reveal excellent performance and are very suitable for making color conversion film arrays applied to Micro-LED displays.

From the foregoing, it will be appreciated that specific embodiments of the invention have been described herein for purposes of illustration, but that various modifications may be made without deviating from the scope of the invention. Accordingly, the invention is not limited except as by the appended claims.

What is claimed is:

1. A color conversion film array, comprising:
a microstructure array comprising a plurality of microstructures, a plurality of first grooves, a plurality of second grooves, and a plurality of third grooves being formed between neighboring microstructures of the plurality of microstructures;
a first color conversion sub-film array comprising a plurality of first color conversion sub-films, wherein each first color conversion sub-film is disposed in one corresponding first groove and comprises a first organic fluorescent material and a first photoresist;
a second color conversion sub-film array comprising a plurality of second color conversion sub-films, wherein each second color conversion sub-film is disposed in one corresponding second groove and comprises a second organic fluorescent material and a second photoresist; and
a shielding layer covering a side wall and an upper surface of each of the plurality of microstructures;
wherein a first side of the color conversion film array is aligned with a micro-LED array to form a micro-LED display.

2. The color conversion film array according to claim 1, wherein each first color conversion sub-film and/or each second color conversion sub-film further comprises inorganic oxide nanoparticles.

3. The color conversion film array according to claim 2, wherein the inorganic oxide nanoparticles comprise TiO₂, SiO₂, ZnO, and/or silver oxide nanoparticles.

4. The color conversion film array according to claim 1, wherein each of the plurality first color conversion sub-films and the plurality of second color conversion sub-films comprises an incident surface adjacent to the micro-LED array and a light-emitting surface, and an area of the incident surface is larger than an area of the light-emitting surface.

5. The color conversion film array according to claim 1, further comprising a color-purifying film on a second side of the color conversion film array.

6. The color conversion film array according to claim 1, further comprising a protective layer between the shielding layer and each of the plurality of first color conversion sub-films and between the shielding layer and each of the plurality of the second color conversion sub-films.

7. The color conversion film array according to claim 1, wherein a resolution of the color conversion film array is greater than 5000 PPI.

8. The color conversion film array according to claim 1, wherein each of the plurality of first color conversion sub-films has a height equal to or less than 3 μm, and each of the plurality of second color conversion sub-films has a height equal or less than 3 μm.
